(19) United States
(12) Patent Application Publication
(10) Pub. No.: US 2026/0020382 A1
(43) Pub. Date: Jan. 15, 2026

(54) LIGHT EMITTING ELEMENT, DISPLAY DEVICE, METHOD FOR MANUFACTURING THE SAME AND ELECTRONIC DEVICE

(71) Applicant: Samsung Display Co., Ltd., Yongin-si (KR)

(72) Inventors: Jong Hyeok LEE, Yongin-si (KR); Byung Choon YANG, Yongin-si (KR); Seok Jin KANG, Yongin-si (KR); Min Woo KIM, Yongin-si (KR); Su Mi MOON, Yongin-si (KR)

(21) Appl. No.: 19/200,517

(22) Filed: May 6, 2025

(30) Foreign Application Priority Data
Jul. 9, 2024 (KR) 10-2024-0090484

(51) Int. Cl. H10H 20/819; H10H 29/49; H10H 29/80

(52) U.S. Cl. CPC H10H 20/819; H10H 29/49; H10H 29/8421

(57) ABSTRACT

A light emitting element, display device, a method for manufacturing the same and an electronic device are provided. A light emitting element includes: a first element rod including a first semiconductor layer and an active layer that are sequentially stacked, and a side surface having a first inclination angle; a second element rod including a second semiconductor layer, and a side surface having a second inclination angle; a first contact electrode on the first element rod; and a second contact electrode having one surface on one surface of the second element rod and a portion of the side surface of the second element rod.

### CROSS-REFERENCE TO RELATED APPLICATION

The present application claims priority to and the benefit of Korean Patent Application No. 10-2024-0090484, filed on Jul. 9, 2024, in the Korean Intellectual Property Office, the entire disclosure of which is incorporated by reference herein.

### BACKGROUND

### 1. Field

The present disclosure relates to a display device, a method for manufacturing the same, and an electronic device.

### 2. Description of the Related Art

As the information society develops, the demand for display devices for displaying images is increasing in various forms. The display device may be a flat panel display device such as a liquid crystal display, a field emission display, or a light emitting display, and/or the like.

The light emitting display device may include an organic light emitting display device including an organic light emitting diode (OLED) element as a light emitting element, and a micro light emitting display device including a micro light emitting diode element (hereinafter referred to as a micro light emitting diode element) as a light emitting element. Because the micro light emitting diode element is made of inorganic materials, it has the advantage of having less deterioration issues and a longer lifespan compared to organic light emitting diode (OLED) elements.

### SUMMARY

Aspects and features of embodiments of the present disclosure are to provide a light emitting element, a display device, and a manufacturing method thereof that may sufficiently secure the area of the active layer.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a light emitting element includes: a first element rod including a first semiconductor layer and an active layer that are sequentially stacked, and a side surface having a first inclination angle; a second element rod including a second semiconductor layer, and a side surface having a second inclination angle; a first contact electrode on the first element rod; and a second contact electrode having one surface on one surface of the second element rod and a portion of the side surface of the second element rod.

According to one or more embodiments, the first contact electrode and the second contact electrode have a columnar shape, wherein one end of the first contact electrode and one end of the second contact electrode are arranged in a straight line on a plane.

According to one or more embodiments, the second inclination angle is smaller than the first inclination angle.

According to one or more embodiments, the first element rod is on the second element rod, wherein a width of the first element rod is smaller than a width of the second element rod at a boundary surface of the first element rod and the second element rod.

According to one or more embodiments, the light emitting element further includes a protective film and a reflective film sequentially located on one side and the side surface of the first element rod and a top surface of the second element rod exposed by the first element rod and having an opening in an area overlapping the first contact electrode and the second contact electrode.

According to one or more embodiments, the reflective film is a distributed Bragg reflector including a first layer and a second layer having different refractive indices.

According to one or more embodiments, a light emitting element includes: a first element rod including a first semiconductor layer and an active layer that are sequentially stacked, and a side surface having a first inclination angle; a second element rod including a second semiconductor layer, and a side surface having a second inclination angle; a first contact electrode on the first element rod; a second contact electrode on the second element rod; and a support on a side of the second element rod and supporting the second contact electrode.

According to one or more embodiments, the second contact electrode and the support include different materials.

According to one or more embodiments, the second contact electrode has higher conductivity than the support, and wherein the support has higher strength than the second contact electrode.

According to one or more embodiments, the first contact electrode, the second contact electrode, and the support have a columnar shape, wherein one end of the first contact electrode, one end of the second contact electrode, and one end the support are in a straight line on a plane, wherein an area at the one end of the first contact electrode is equal to a sum of an area at the one end of the second contact electrode and an area at the one end of the support.

According to one or more embodiments, a display device including: a substrate; a pixel electrode and a common electrode spaced from each other on the substrate; and a light emitting element on the pixel electrode and the common electrode, wherein the light emitting element includes: a first element rod including a first semiconductor layer and an active layer that are sequentially stacked, and a side surface having a first inclination angle; a second element rod including a second semiconductor layer, and a side surface having a second inclination angle; a first contact electrode on the first element rod and connected to the pixel electrode; and a second contact electrode having one side on one side of the second element rod and a portion of the side surface of the second element rod, and connected to the common electrode.

According to one or more embodiments, the first contact electrode and the second contact electrode have a columnar shape, wherein one end of the first contact electrode and one end of the second contact electrode are in a straight line on a plane.

According to one or more embodiments, the second inclination angle is smaller than the first inclination angle.

According to one or more embodiments, the first element rod is on the second element rod, wherein a width of the first element rod is smaller than a width of the second element rod at a boundary surface of the first element rod and the second element rod.

According to one or more embodiments, the display device further includes a first connection electrode connecting the first contact electrode and the pixel electrode and a second connection electrode connecting the second contact electrode and the common electrode.

According to one or more embodiments, the display device further includes an organic layer between the light emitting element and the pixel electrode and the common electrode.

According to one or more embodiments, a display device including: a substrate; a pixel electrode and a common electrode spaced from each other on the substrate; and a light emitting element on the pixel electrode and the common electrode, wherein the light emitting element includes: a first element rod including a first semiconductor layer and an active layer that are sequentially stacked, and a side surface having a first inclination angle; a second element rod including a second semiconductor layer, and a side surface having a second inclination angle; a first contact electrode on the first element rod; a second contact electrode on the second element rod; and a support on a side of the second element rod and supporting the second contact electrode.

According to one or more embodiments, a manufacturing method of a display device includes: forming a light emitting element on a growth substrate; and transferring the light emitting element onto a substrate, wherein the forming the light emitting element includes: forming a first semiconductor material layer, an active material layer, and a second semiconductor material layer on the growth substrate; etching a portion of the first semiconductor material layer and the active material layer to form a first element rod having a first inclination angle on a side surface of the first element rod; forming a protective film and a reflective film covering the first element rod; etching the second semiconductor material layer to form a second element rod having a second inclination angle on a side surface of the second element rod; and forming a first contact electrode on the first element rod and forming a second contact electrode on one surface and the side surface of the second element rod.

According to one or more embodiments, the forming the first contact electrode on the first element rod and the forming the second contact electrode on the one side and the side surface of the second element rod includes: filling a space between the first element rod and the second element rod with a filler; forming a first opening exposing the first element rod and a second opening exposing the one side and a portion of the side surface of the second element rod; forming the first contact electrode in the first opening and the second contact electrode in the second opening; flattening top surfaces of the first contact electrode and the second contact electrode; and removing the filler.

According to one or more embodiments, a manufacturing method of a display device includes: forming a light emitting element on a growth substrate; and transferring the light emitting element onto a substrate, wherein the forming the light emitting element includes: forming a first semiconductor material layer, an active material layer, and a second semiconductor material layer on the growth substrate; etching a portion of the first semiconductor material layer and the active material layer to form a first element rod having a first inclination angle on a side surface of the first element rod; forming a protective film and a reflective film covering the first element rod; etching the second semiconductor material layer to form a second element rod having a second inclination angle on a side surface of the second element rod; forming a support on the side surface of the second element rod; and forming a first contact electrode on the first element rod and a second contact electrode on one surface of the second element rod.

According to one or more embodiments, an electronic device includes: a display device for displaying an image, wherein the display device includes: a substrate; a pixel electrode and a common electrode spaced from each other on the substrate; and a light emitting element on the pixel electrode and the common electrode, wherein the light emitting element includes: a first element rod including a first semiconductor layer and an active layer that are sequentially stacked, and a side surface having a first inclination angle; a second element rod including a second semiconductor layer, and a side surface having a second inclination angle; a first contact electrode on the first element rod and connected to the pixel electrode; and a second contact electrode having one side on one side of the second element rod and a portion of the side surface of the second element rod, and connected to the common electrode.

The display device and the manufacturing method thereof according to one or more embodiments, the light emitting efficiency may be improved by sufficiently securing the area of the active layer.

According to one or more embodiments, the manufacturing cost of the light emitting element may be reduced by using a support.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to one or more embodiments.

FIG. 2 is a layout drawing illustrating a display device according to one or more embodiments.

FIG. 3 is a block drawing illustrating a display device according to one or more embodiments.

FIG. 4 is an equivalent circuit drawing illustrating a sub-pixel according to one or more embodiments.

FIG. 5 is a layout drawing illustrating pixels of a display area according to one or more embodiments.

FIG. 6 is a cross-sectional view illustrating one example of a cross-section of a display panel corresponding to the line I-I′ in FIG. 5.

FIG. 7 is a cross-sectional view illustrating one example of an area A1 of FIG. 6 in detail.

FIG. 8 is a cross-sectional view illustrating another example of the area A1 of FIG. 6 in detail.

FIG. 9 is a cross-sectional view illustrating another example of the area A1 of FIG. 6 in detail.

FIG. 10 is a cross-sectional view illustrating another example of the area A1 of FIG. 6 in detail.

FIG. 11 is a cross-sectional view illustrating another example of the area A1 of FIG. 6 in detail.

FIG. 12 is a layout drawing illustrating pixels of a display area according to one or more embodiments.

FIG. 13 is a cross-sectional view illustrating another example of a cross-section of a display panel corresponding to the lines I1-I1′, I2-I2′, and I3-I3′ of FIG. 12.

FIG. 14 is a cross-sectional view illustrating one example of an area A2 of FIG. 13 in detail.

FIG. 15 is a flowchart illustrating a method for manufacturing a display device according to one or more embodiments.

FIG. 16 is a flowchart illustrating a method for manufacturing a light emitting element of step S100 of FIG. 15.

FIGS. 17-28 are example drawings to illustrate a method for manufacturing a display device.

FIGS. 29-32 are example drawings to illustrate step S150 of FIG. 16 according to one or more other embodiments.

FIG. 33 is an example view of a smart watch including a display device according to one or more embodiments;

FIGS. 34 and 35 are example views of a virtual reality (VR) device including a display device according to one or more embodiments;

FIG. 36 is an example view of a VR device including a display device according to one or more embodiments;

FIG. 37 is an example view illustrating a vehicle instrument cluster and center fascia including display devices according to one or more embodiments; and

FIG. 38 is an example view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), and/or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

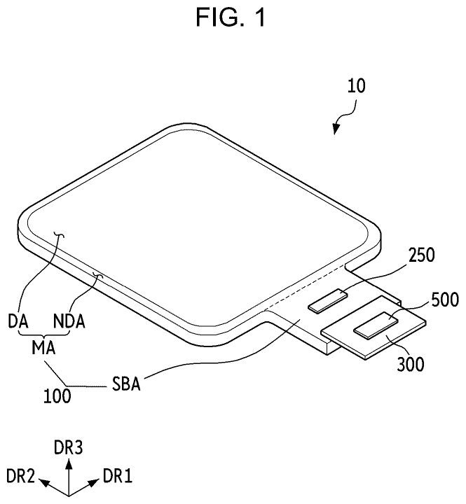

FIG. 1 is a perspective view of a display device 10 according to one or more embodiments.

Referring to FIG. 1, the display device 10 is a device for displaying moving images and/or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and/or Internet of things (IoT) devices.

The display device 10 may be a light emitting display such as an organic light emitting display using an organic light emitting diode (OLED), a quantum dot light emitting display including a quantum dot light emitting layer, an inorganic light emitting display including an inorganic semiconductor, or a micro- or nano-light emitting display using a micro- or nano-light emitting diode (LED). A case where the display device 10 is a micro- or nano-light emitting display will be mainly described below, but the present disclosure is not limited thereto. For ease of description, a micro- or nano-LED will be referred to as a light emitting element.

The display device 10 includes a display panel 100, a display driving circuit 250, a circuit board 300, and a power supply unit 500.

The display panel 100 may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded to have a suitable curvature (e.g., a predetermined curvature) or may be right-angled. The planar shape of the display panel 100 is not limited to a quadrangular shape but may also be other polygonal shapes, a circular shape, and/or an elliptical shape. The display panel 100 may be formed flat, but the present disclosure is not limited thereto. For example, the display panel 100 may include a curved portion formed at left and right ends and having a constant or varying curvature. In addition, the display panel 100 may be formed to be flexible so that it can be curved, bent, folded, and/or rolled.

A substrate SUB of the display panel 100 may include a main area MA and a sub-area SBA.

The main area MA may include a display area DA that displays an image and a non-display area NDA disposed around the display area DA along an edge or a periphery of the display area DA. The display area DA may include a plurality of pixels that displays an image. Each of the pixels may include a plurality of subpixels. For example, each of the pixels may include a first subpixel that emits light of a first color, a second subpixel that emits light of a second color, and a third subpixel that emits light of a third color, but the present disclosure is not limited thereto.

The sub-area SBA may protrude from a side of the main area MA in the second direction DR2. Although the sub-area SBA is unfolded in FIG. 1, it may be bent. In this case, the sub-area SBA may be placed on a lower surface of the display panel 100. When the sub-area SBA is bent, it may be overlapped by the main area MA in a third direction DR3 which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached onto the display panel 100 using a chip on glass (COG) method, a chip on plastic (COP) method, and/or an ultrasonic bonding method. However, the present disclosure is not limited thereto. For example, the display driving circuit 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip on film (COF).

The power supply unit 500 may generate a plurality of panel driving voltages according to a power supply voltage from the outside. The power supply unit 500 may be formed as an integrated circuit (IC) and attached onto the circuit board 300 using a COF method.

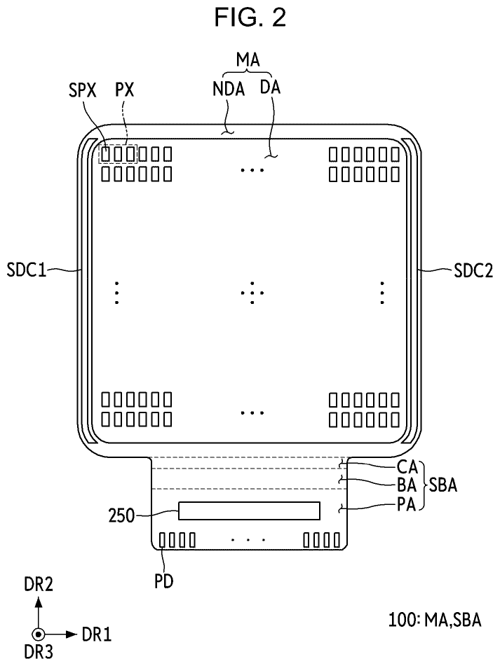

FIG. 2 is a layout view of the display device 10 according to one or more embodiments. FIG. 2 illustrates a state in which the sub-area SBA is unfolded without being bent.

Referring to FIG. 2, the display panel 100 may include the main area MA and the sub-area SBA.

The main area MA may include the display area DA that displays an image and the non-display area NDA disposed around the display area DA. The display area DA may occupy most of the main area MA. The display area DA may be disposed in a center of the main area MA.

The display area DA may include a plurality of pixels PX for displaying an image, and each of the pixels PX may include a plurality of subpixels SPX. A pixel PX may be defined as a smallest subpixel group that can express a white gray level.

The non-display area NDA may neighbor the display area DA. The non-display area NDA may be an area outside the display area DA. The non-display area NDA may be around (e.g., may surround) the display area DA. The non-display area NDA may be an edge area of the display panel 100.

A first scan driver SDC1 and a second scan driver SDC2 may be disposed in the non-display area NDA. The first scan driver SDC1 may be disposed on a side (e.g., a left side) of the display panel 100, and the second scan driver SDC2 may be disposed on the other side (e.g., a right side) of the display panel 100. However, the present disclosure is not limited thereto.

Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output the scan signals to scan lines.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and the other side of the connection area CA may contact the bending area BA.

The pad area PA is an area where pads PD and the display driving circuit 250 are disposed. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. A side of the pad area PA may contact the bending area BA.

The bending area BA is a bendable area. When the bending area BA is bent, the pad area PA may be placed under the connection area CA and the main area MA. The bending area BA may be disposed between the connection area CA and the pad area PA. A side of the bending area BA may contact the connection area CA, and the other side of the bending area BA may contact the pad area PA.

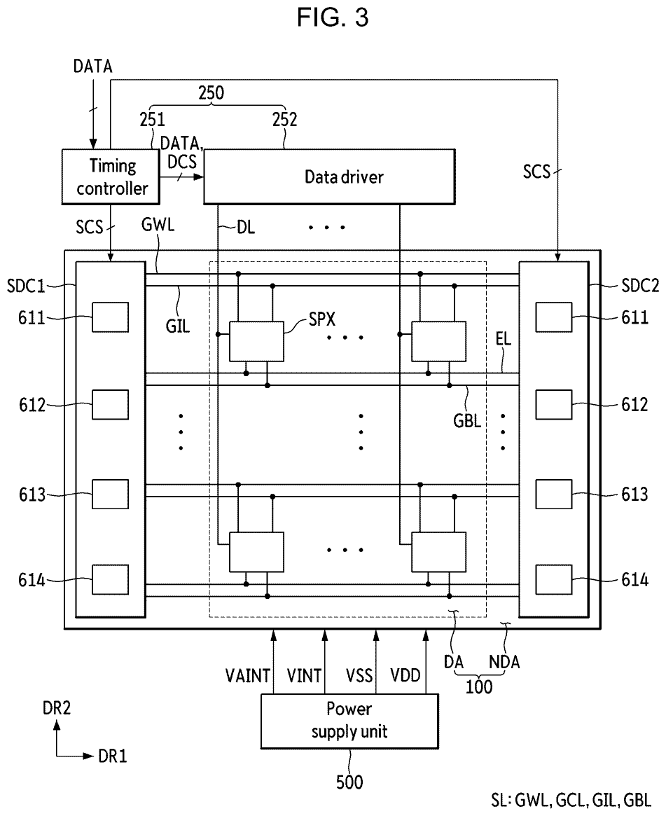

FIG. 3 is a block diagram of the display device 10 according to one or more embodiments.

Referring to FIG. 3, the display area DA includes a plurality of pixels PX including a plurality of sub-pixels SPX, a plurality of scan lines SL, a plurality of emission control lines EL, and a plurality of data lines DL.

The pixels PX may be arranged in a matrix form along the first direction DR1 and the second direction DR2. For example, the pixels PX may be arranged along rows and columns of a matrix form along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. The scan lines SL include a plurality of write scan lines GWL, a plurality of initialization scan lines GIL, and a plurality of bias scan lines GBL.

Each of the subpixels SPX may be connected to one of the write scan lines GWL, one of the initialization scan lines GIL, one of the bias scan lines GBL, one of the emission control lines EL, and one of the data lines DL. In one or more embodiments, each of the subpixels SPX may also be connected to one of the control scan lines. Each of the subpixels SPX may receive a data voltage of a data line DL according to a write scan signal of a write scan line GWL and may emit light from a light emitting element according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, an initialization scan signal output unit 612, a bias scan signal output unit 613, and an emission signal output unit 614. Each of the write scan signal output unit 611, the initialization scan signal output unit 612, the bias scan signal output unit 613, and the emission signal output unit 614 may receive a scan timing control signal SCS from a timing controller 251. The write scan signal output unit 611 may generate write scan signals according to the scan timing control signal SCS of the timing controller 251 and sequentially output the write scan signals to the write scan lines GWL. The initialization scan signal output unit 612 may generate initialization scan signals according to the scan timing control signal SCS and sequentially output the initialization scan signals to the initialization scan lines GIL. The bias scan signal output unit 613 may generate bias scan signals according to the scan timing control signal SCS and sequentially output the bias scan signals to the bias scan lines GBL. The emission signal output unit 614 may generate emission control signals according to the scan timing control signal SCS and sequentially output the emission control signals to the emission control lines EL. In one or more other embodiments, a control scan signal output unit of the first scan driver SDC1 and the second scan driver SDC2 may generate control scan signals according to the scan timing control signal SCS and sequentially output the control scan signals to the control scan lines.

The display driving circuit 250 includes the timing controller 251 and a data driver 252.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by write scan signals of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power supply voltage from the outside. For example, the power supply unit 500 may generate a first power supply voltage VDD, a second power supply voltage VSS, a third power supply voltage VINT, and a fourth power supply voltage VAINT and supply them to the display panel 100.

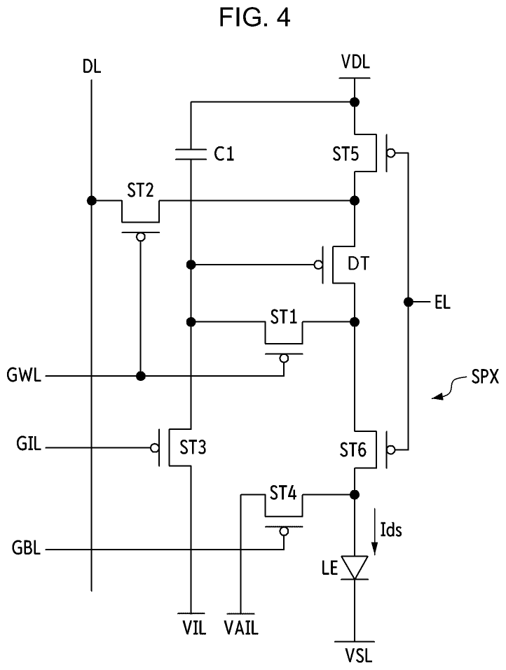

FIG. 4 is an equivalent circuit diagram of a subpixel SPX according to one or more embodiments.

Referring to FIG. 4, the subpixel SPX according to the embodiment may be connected to scan lines GWL, GIL, and GBL, an emission control line EL, and a data line DL. For example, the subpixel SPX may be connected to a write scan line GWL, an initialization scan line GIL, a bias scan line GBL, the emission control line EL, and the data line DL.

The subpixel SPX according to the embodiment includes a driving transistor DT, switch elements, a capacitor C1, and a light emitting element LE. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode of the driving transistor DT according to a data voltage applied to the gate electrode of the driving transistor DT.

The light emitting element LE may be a micro-LED.

The light emitting element LE emits light according to the driving current Ids. The amount of light emitted from the light emitting element LE may be proportional to the driving current Ids. An anode of the light emitting element LE may be connected to a first electrode of the fourth transistor ST4 and a second electrode of the sixth transistor ST6, and a cathode may be connected to a second power line VSL to which the second power supply voltage VSS is applied.

The capacitor C1 is formed between the gate electrode of the driving transistor DT and a first power line VDL to which the first power supply voltage VDD is applied. The first power supply voltage VDD may be at a higher level than the second power supply voltage VSS. One electrode of the capacitor C1 may be connected to the gate electrode of the driving transistor DT, and the other electrode may be connected to the first power line VDL.

As illustrated in FIG. 4, the first through sixth transistors ST1 through ST6 and the driving transistor DT may all be formed as p-type metal-oxide-semiconductor field effect transistors (MOSFETs). In this case, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and a gate electrode of the fifth transistor ST5 and a gate electrode of the sixth transistor ST6 may be connected to the emission control line EL. Because the first through sixth transistors ST1 through ST6 are formed as p-type MOSFETs, they may be turned on when a scan signal of a gate-low voltage and an emission control signal of a gate-low voltage are transmitted the initialization scan line GIL, the write scan line GWL, the bias scan line GBL, and the emission control line EL. One electrode of the third transistor ST3 and one electrode of the fourth transistor ST4 may be connected to an initialization voltage line VIL and the voltage line VAIL, respectively.

Alternatively, the driving transistor DT, the second transistor ST2, the fourth transistor ST4, the fifth transistor ST5, and the sixth transistor ST6 may be formed as p-type MOSFETs, and the first transistor ST1 and the third transistor ST3 may be formed as n-type MOSFETs. The active layer of each of the driving transistor DT, the second transistor ST2, the fourth transistor ST4, the fifth transistor ST5, and the sixth transistor ST6 formed as p-type MOSFETs may be made of polysilicon, and the active layer of each of the first transistor ST1 and the third transistor ST3 formed as n-type MOSFETs may be made of an oxide semiconductor.

In this case, because the first transistor ST1 and the third transistor ST3 are formed as n-type MOSFETs, the first transistor ST1 may be turned on in response to a write scan signal of a gate-high voltage, and the third transistor ST3 may be turned on in response to an initialization scan signal of a gate-high voltage. On the other hand, because the second transistor ST2, the fourth transistor ST4, the fifth transistor ST5, and the sixth transistor ST6 are formed as p-type MOSFETs, they may be turned on in response to a scan signal of a gate-low voltage and an emission control signal of a gate-low voltage.

Alternatively, the fourth transistor ST4 may be formed as an n-type MOSFET. In this case, the active layer of the fourth transistor ST4 may be made of an oxide semiconductor. When the fourth transistor ST4 is formed as an n-type MOSFET, it may be turned on in response to a bias scan signal of a gate-high voltage.

Alternatively, the first through sixth transistors ST1 through ST6 and the driving transistor DT may all be formed as n-type MOSFETs. In this case, the active layer of each of the first through sixth transistors ST1 through ST6 and the driving transistor DT may be made of an oxide semiconductor.

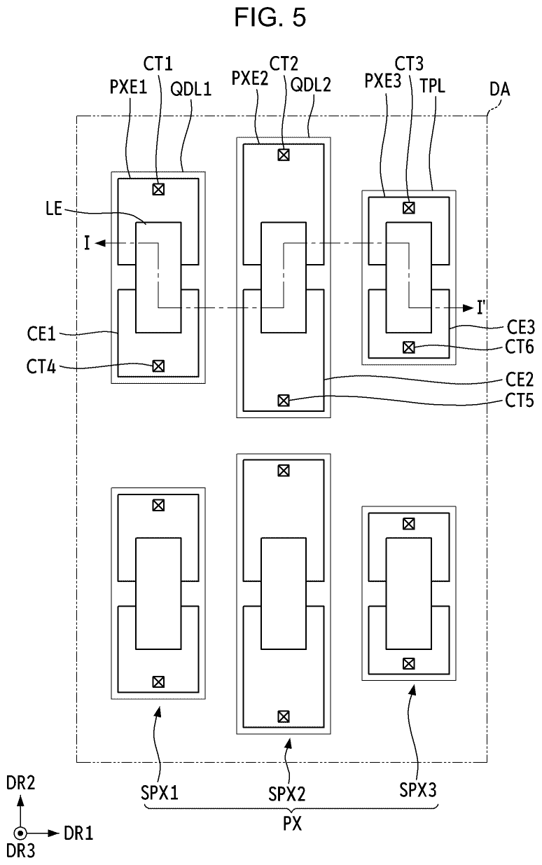

FIG. 5 is a layout drawing illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels, the sub-pixels may be the first sub-pixel SPX1, the second sub-pixel SPX2, and the third sub-pixel SPX3.

The plurality of pixels PX may be disposed in a matrix form. In each of the plurality of pixels PX, the first sub-pixel SPX1, the second sub-pixel SPX2, and the third sub-pixel SPX3 may be disposed along the first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a blue wavelength band, the second color light may be light in a green wavelength band, and the third color light may be light in a red wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, a first common electrode CE1, a plurality of light emitting elements LE, and a first light conversion layer QDL1. The second sub-pixel SPX2 includes a second pixel electrode PXE2, a second common electrode CE2, the plurality of light emitting elements LE, and the second light conversion layer QDL2. The third sub-pixel SPX3 includes a third pixel electrode PXE3, a third common electrode CE3, a plurality of light emitting elements LE, and a light transmission layer TPL.

In each of the first sub-pixel SPX1, the second sub-pixel SPX2, and the third sub-pixel SPX3, the pixel electrodes PXE1, PXE2, and PXE3 and the common electrodes CE1, CE2, and CE3 may be arranged along the second direction DR2. Each of the pixel electrodes PXE1, PXE2, and PXE3 and the common electrodes CE1, CE2, and CE3 may have a rectangular planar shape, but the present disclosure is not limited thereto. The area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3, but the present disclosure is not limited thereto.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1, and the area of the second common electrode CE2 may be larger than the area of the first common electrode CE1. Also, while the light transmission layer TPL transmits light of the light emitting element LE as it is, the first light conversion layer QDL1 need to convert the light. Therefore, the area of the first pixel electrode PXE1 may be larger than the area of the third pixel electrode PXE3, and the area of the first common electrode CE1 may be larger than the area of the third common electrode CE3.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

The first common electrode CE1 may be connected to the second power supply line VSL to which a second driving voltage VSS is applied through a first common connection hole CT4. The second common electrode CE2 may be connected to the second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3. The pixel electrodes PXE1, PXE2, and PXE3 may be referred to as an anode electrode or a first electrode, and the common electrode CE may be referred to as a cathode electrode or a second electrode.

The plurality of light emitting elements LE may be disposed on the pixel electrodes PXE1, PXE2, and PXE3 and the common electrodes CE1, CE2, and CE3. Each of the plurality of light emitting elements LE may have a rectangular planar shape, but the present disclosure is not limited thereto. For example, each of the plurality of light emitting elements LE may have a circular planar shape.

The first light conversion layer QDL1 may completely overlap the plurality of light emitting elements LE of the first sub-pixel SPX1. The first light conversion layer QDL1 may convert or shift the peak wavelength of incident light into light of another specific peak wavelength and emit it. For example, the first light conversion layer QDL1 may convert or shift the third light emitted from the plurality of light emitting elements LE of the first sub-pixel SPX1 into first light.

The second light conversion layer QDL2 may completely overlap the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into second light.

The light transmission layer TPL may completely overlap the plurality of light emitting elements LE of the third sub-pixel SPX3. The light transmission layer TPL may transmit incident light as it is. For example, the light transmission layer TPL may directly transmit the third light emitted from the plurality of light emitting elements LE of the third sub-pixel SPX3.

When the light emitting element LE of the first sub-pixel SPX1 emits light of the first color, the light emitting element LE of the second sub-pixel SPX2 emits light of the second color, and the light emitting element LE of the third sub-pixel SPX3 emits light of the third color, the light conversion layers QDL1 and QDL2 and the light transmission layer TPL may be omitted.

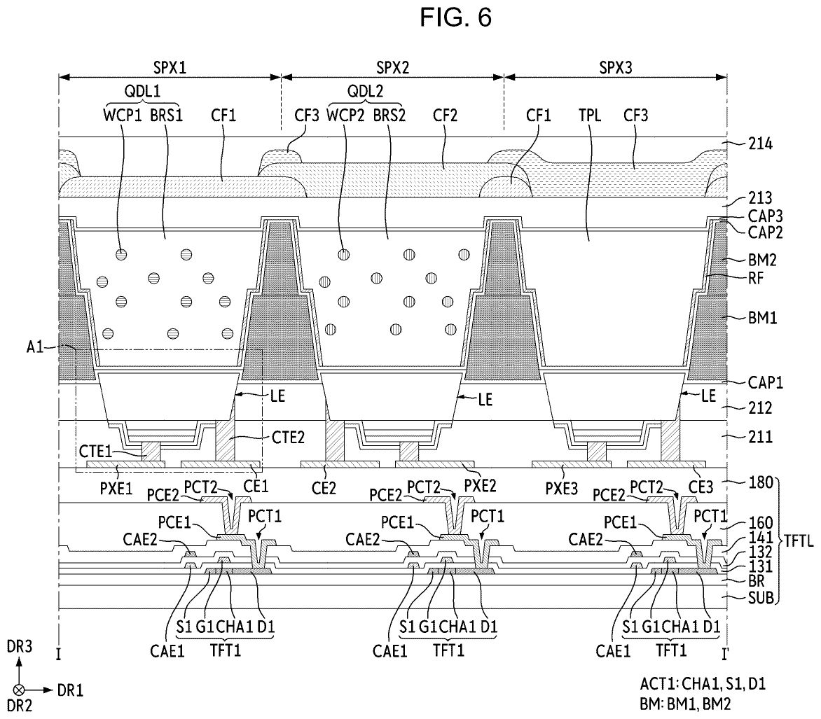

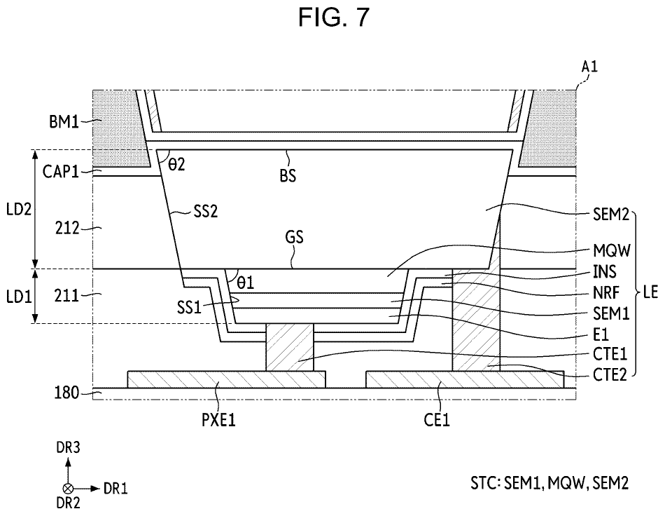

FIG. 6 is a cross-sectional view illustrating one example of a cross-section of a display panel corresponding to the line I-I′ in FIG. 5. FIG. 7 is a cross-sectional view illustrating one example of an area A1 of FIG. 6 in detail.

Referring to FIGS. 6 and 7, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be disposed on the substrate SUB. The barrier film BR is a film that protects the transistors of the thin film transistor layer TFTL from moisture penetrating through the substrate SUB, which is vulnerable to moisture penetration. The barrier film BR may be composed of a plurality of inorganic films stacked alternately.

A thin film transistor TFT1 may be disposed on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, and/or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and/or oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1 and on the barrier film BR.

A first gate metal layer may be disposed on a first gate insulating film 131. The first gate metal layer may include the first gate electrode G1 and the first capacitor electrode CAE1 of the thin film transistor TFT1. The first gate electrode G1 may overlap the first active layer ACT1 in the third direction DR3. In FIG. 6, the first gate electrode G1 and the first capacitor electrode CAE1 are shown to be spaced (e.g., spaced apart) from each other, but the first gate electrode G1 and the first capacitor electrode CAE1 may be connected to each other.

A second gate insulating film 132 may be disposed on the first gate electrode G1 of the thin film transistor TFT1, the first capacitor electrode CAE1, and the first gate insulating film 131.

A second gate metal layer may be disposed on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2 and the second gate insulating film 132.

A first data metal layer may be disposed on the interlayer insulating film 141. The first data metal layer may include a first source connection electrode PCE1. The first source connection electrode PCE1 may be connected to a first drain area D1 of the first active layer ACT1 through a first source contact hole PCT1 penetrating the first gate insulating film 131, the second gate insulating film 132, and the interlayer insulating film 141.

A first planarization organic film 160 may be disposed on the first source connection electrode PCE1 and the interlayer insulating film 141 to planarize a step caused by the thin film transistor TFT1.

A second data metal layer may be disposed on the first planarization organic film 160. The second data metal layer may include a second source connection electrode PCE2. The second source connection electrode PCE2 may be connected to the first source connection electrode PCE1 through a second pixel contact hole PCT2 penetrating the first planarization organic film 160.

A second planarization film 180 may be disposed on the second source connection electrode PCE2 and the first planarization organic film 160.

The barrier film BR, the first gate insulating film 131, the second gate insulating film 132, and the interlayer insulating film 141 may be formed of an inorganic film, for example, silicon nitride (SiNₓ), silicon oxide (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization film 180 may be formed from an organic film such as an acrylic resin, an epoxy resin, a phenolic resin, a polyamide resin, a polyimide resin, and/or the like.

A light emitting element layer may be disposed on the second planarization film 180. The light emitting element layer may include pixel electrodes PXE1, PXE2, and PXE3, light emitting elements LE, a common electrodes CE1, CE2, and CE3, and organic films 211 and 212.

A pixel electrode layer may be disposed on the second planarization film 180. The pixel electrode layer may include pixel electrodes PXE1, PXE2, and PXE3 and common electrodes CE1, CE2, and CE3. The pixel electrode layer may be disposed on the second planarization film 180.

Each of the first pixel electrode PXE1, the second pixel electrode PXE2, and the third pixel electrode PXE3 may be connected to the second source connection electrode PCE2 through a pixel connection hole (CT1, CT2, and CT3 in FIG. 5) penetrating the second planarization film 180. Each of the pixel electrodes PXE1, PXE2, and PXE3 may be connected to a first source area S1 or a first drain area D1 of the thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrodes CE1, CE2, and CE3 may be connected to a second power supply line (VSL in FIG. 4) to which a second driving voltage (VSS in FIG. 3) is applied through the common connection hole (CT4, CT5, and CT6 in FIG. 5). The first common electrode CE1 may be connected to the second power supply line (VSL in FIG. 4) through the first common connection hole CT4. The second common electrode CE2 may be connected to the second power supply line (VSL in FIG. 4) through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers molybdenum (Mo), aluminum (Al), chromium (Cr), gold (Au), titanium (Ti), nickel (Ni), neodymium (Nd), and/or copper (Cu), and/or alloys thereof. For example, the pixel electrode layer may be made of copper (Cu) with low sheet resistance to lower the resistance of each of the pixel electrodes PXE1, PXE2, and PXE3.

A plurality of light emitting elements LE may be disposed on the pixel electrode layer. In FIGS. 6 and 7, the light emitting elements LE are illustrated as flip-type micro LED. The flip-type micro LED refers to an LED in which contact electrodes CTE1 and CTE2 are formed on one surface (e.g., the bottom surface) of the light emitting element LE.

Each of the plurality of light emitting elements LE may be formed from an inorganic material such as gallium nitride (GaN). Each of the plurality of light emitting elements LE may have a length in the first direction DR1, a length in the second direction DR2, and a length in the third direction DR3 of several to several hundred μm, respectively. For example, each of the plurality of light emitting elements LE may have a length in the first direction DR1, a length in the second direction DR2, and a length in the third direction DR3 of approximately 100 μm or less, respectively.

Each of the plurality of light emitting elements LE may be formed by growing on a semiconductor substrate, such as a silicon substrate or a sapphire substrate. The plurality of light emitting elements LE may be transferred onto the pixel electrode layer of the display panel 100 directly from the semiconductor substrate or through a relay substrate. Alternatively, the plurality of light emitting elements LE may be transferred onto the pixel electrodes PXE1, PXE2, and PXE3 of the display panel 100 through an electrostatic method using an electrostatic head or a stamp method using an elastic polymeric material such as polydimethylsiloxane (PDMS) or silicone as a transfer substrate.

The light emitting element LE may include a conductive layer E1, a first semiconductor layer SEM1, an active layer MQW, a second semiconductor layer SEM2, a first contact electrode CTE1, a second contact electrode CTE2, and a protective film INS.

The conductive layer E1 may be disposed on one surface of the first semiconductor layer SEM1. For example, the conductive layer E1 may be disposed on a portion of the bottom surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be disposed on the conductive layer E1. The first semiconductor layer SEM1 may include a semiconductor material layer doped with a first conductive dopant, such as magnesium (Mg), zinc (Zn), calcium (Ca), strontium (Sr), barium (Ba), and/or the like, for example gallium nitride (GaN).

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) or aluminum gallium nitride (AlGaN), but the present disclosure is not limited thereto.

Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

In one or more embodiments, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (light in the blue wavelength band) may be approximately 10 wt % to 20 wt %.

The second semiconductor layer SEM2 may be disposed on the active layer MQW. The second semiconductor layer SEM2 may be a semiconductor material layer doped with a second conductivity type dopant such as silicon (Si), germanium (Ge), tin (Sn), etc., for example, gallium nitride (GaN).

An electron blocking layer may be disposed between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The light emitting element LE may be divided into a first element rod LD1, a second element rod LD2, a first contact electrode CTE1, and a second contact electrode CTE2.

The first element rod LD1 may have a first side surface SS1 with a first inclination angle θ1 and may include the conductive layer E1, the first semiconductor layer SEM1, and the active layer MQW. The first inclination angle θ1 may be an angle formed between a boundary surface GS of the first element rod LD1 and the second element rod LD2 and the first side surface SS1.

The second element rod LD2 may have a second side surface SS2 with a second inclination angle θ2 and may include the second semiconductor layer SEM2. The second inclination angle θ2 may be an angle formed between the bottom surface BS of the second element rod LD2. The first inclination angle θ1 may be the same as the second inclination angle θ2 but is not limited thereto. For example, the first inclination angle θ1 may be greater than the second inclination angle θ2.

The first element rod LD1 is disposed on the second element rod LD2. The width of the first element rod LD1 is smaller than the width of the second element rod LD2. Therefore, the first element rod LD1 may be fully overlapped with the second element rod LD2. At least a portion of one side of the second element rod LD2 may be exposed.

At the boundary between the first element rod LD1 and the second element rod LD2, the width of the first element rod LD1 is smaller than the width of the second element rod LD2. At least a portion of the second element rod LD2 does not overlap with the first element rod LD1 and its upper surface is exposed.

A first contact electrode CTE1 is disposed on one side of the first element rod LD1. The first contact electrode CTE1 may be disposed on at least a portion of the conductive layer E1. The first contact electrode CTE1 may include molybdenum (Mo), aluminum (Al), chromium (Cr), gold (Au), titanium (Ti), nickel (Ni), neodymium (Nd), and/or copper (Cu). In one or more embodiments, the first contact electrode CTE1 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO).

One side of the second contact electrode CTE2 may be disposed on one side of the second element rod LD2 and at least a portion of a side surface adjacent to the one side of the second element rod LD2. The second contact electrode CTE2 may include molybdenum (Mo), aluminum (Al), chromium (Cr), gold (Au), titanium (Ti), nickel (Ni), neodymium (Nd), and/or copper (Cu). In one or more embodiments, the second contact electrode CTE2 may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO).

The first contact electrode CTE1 and the second contact electrode CTE2 may be spaced (e.g., spaced apart) from each other in the first direction and/or the second direction DR2. The first contact electrode CTE1 and the second contact electrode CTE2 may have a columnar shape extending in the third direction DR3. The first contact electrode CTE1 and the second contact electrode CTE2 may have the same area on a plane. In this disclosure, “on a plane” is set based on a plane parallel to the plane defined by the first direction DR1 and the second direction DR2.

One end of the first contact electrode CTE1 and one end of the second contact electrode CTE2 are disposed on the same straight line. Therefore, when the light emitting element LE is disposed on the pixel electrode PXE1, PXE2, and PXE3 and the common electrode CE1, CE2, and CE3 disposed on the same layer, it may be disposed without being biased to one side or falling over.

The protective film INS may be a film for protecting one side and the side surface of the first element rod LD1. For example, the protective film INS may be disposed on the bottom surface and the side surface of the conductive layer E1, the side surface of the first semiconductor layer SEM1, and the side surface of the active layer MQW. The protective film INS has an opening at a position overlapping the first contact electrode CTE1 on the first element rod LD1.

In addition, the protective film INS may extend from the side of the first element rod LD1 to one side of the second element rod LD2. The protective film INS may not be disposed on the side of the second element rod LD2. The protective film INS has an opening at a position overlapping the second contact electrode CTE2 on the second element rod LD2.

The protective film INS may be formed of an inorganic film, for example, silicon nitride (SiNₓ), silicon oxide (SiON), silicon oxide (SiOₓ), titanium oxide (TiOₓ), and/or aluminum oxide (AlOₓ).

A reflective film NRF may be disposed on the protective film INS. The reflective film NRF may be disposed on the bottom surface and side surface of the conductive layer E1, the side surface of the first semiconductor layer SEM1, and the side surface of the active layer MQW on the protective film INS. Further, the reflective film NRF may extend from the side surface of the first element rod LD1 to one surface of the second element rod LD2. The reflective film NRF may not be disposed on the side surface of the second element rod LD2.

The reflective film NRF may be a distributed Bragg reflector (DBR) including a first layer and a second layer of M pairs (M is an integer greater than or equal to 2) having different refractive indices. In this case, the M first layers and the M second layers may be disposed alternately. The first layer and the second layer may be formed of an inorganic film, such as a silicon nitride layer, a silicon oxynitride layer, a silicon oxide layer, a titanium oxide layer, and/or an aluminum oxide layer.

The second organic film 211 may be disposed to cover a portion of the side surface of the plurality of light emitting elements LE. Further, the second organic film 211 may be disposed to cover the pixel electrodes PXE1, PXE2, and PXE3 and the common electrodes CE1, CE2, and CE3 and fill the space between the light emitting elements LE.

The third organic film 212 may be disposed on the second organic film 211. The third organic film 212 may be disposed to cover another portion of the side surface of each of the plurality of light emitting elements LE. The upper surface of each of the plurality of light emitting elements LE may be exposed without being covered by the third organic film 212.

The second organic film 211 and the third organic film 212 are layers for flattening the step caused by the plurality of light emitting elements LE. When the height of the second organic film 211 is disposed to cover most of the sides of each of the plurality of light emitting elements LE, the third organic film 212 may be omitted.

The second organic film 211 and the third organic film 212 may be formed from an organic film such as an acrylic resin, an epoxy resin, a phenolic resin, a polyamide resin, a polyimide resin, and/or the like.

A first capping layer CAP1 may be disposed on the third organic film 212 and the light emitting element LE.

A light blocking layer BM (BM1, BM2), a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be formed by the compartments the light blocking layer BM. Therefore, the first light conversion layer QDL1 may be disposed on the first capping layer CAP1 in the first sub-pixel SPX1, the second light conversion layer QDL2 may be disposed on the first capping layer CAP1 in the second sub-pixel SPX2, and the light transmission layer TPL may be disposed on the first capping layer CAP1 in the third sub-pixel SPX3. The light blocking layer BM may not overlap the plurality of light emitting elements LE in the third direction DR3.

The first light conversion layer QDL1 may convert a portion of the third light (light in the blue wavelength band) incident from the light emitting element LE into first light (light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light emitting element LE into first light (light in the red wavelength band).

The second light conversion layer QDL2 may convert a portion of the third light (light in the blue wavelength band) incident from the light emitting element LE into second light (light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light emitting element LE into second light (light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cardo-based resin, and/or an imide-based resin. The first and second wavelength conversion particles WCP1 and WCP2 may be quantum dots (QD), quantum rods, fluorescent materials, and/or phosphorescent materials.

The light blocking layer BM may include a first light blocking layer BM1 and a second light blocking layer BM2 that are sequentially stacked. A length of the first light blocking layer BM1 in the first direction DR1 or the second direction DR2 may be wider than a length of the second light blocking layer BM2 in the first direction DR1 or the second direction DR2. The first light blocking layer BM1 and the second light blocking layer BM2 may be formed of an organic film such as an acrylic resin, an epoxy resin, a phenolic resin, a polyamide resin, a polyimide resin, and/or the like. The first light blocking layer BM1 and the second light blocking layer BM2 may include a light blocking material to prevent light from the light emitting element LE of one sub-pixel from proceeding to the neighboring sub-pixel. For example, the first light blocking layer BM1 and the second light blocking layer BM2 may include an inorganic black pigment such as carbon black and/or an organic black pigment.

The second capping layer CAP2 may be disposed on the first capping layer CAP1 and the light blocking layer BM. The second capping layer CAP2 may be disposed on the side and top surfaces of the light blocking layer BM. That is, the second capping layer CAP2 may be disposed on the side of the first light blocking layer BM1 and the side and top surfaces of the second light blocking layer BM2.

A reflective film RF may be disposed between the light blocking layer BM and the first light conversion layer QDL1, between the light blocking layer BM and the second light conversion layer QDL2, and between the light blocking layer BM and the light transmission layer TPL. The reflective film RF may be disposed on the second capture layer CAP2 disposed on the side of the first light blocking layer BM1 and the side of the second light blocking layer BM2. The reflective film RF serves to reflect light traveling in the lateral direction from the first light conversion layer QDL1, the second light conversion layer QDL2, and the light transmission layer TPL.

The reflective film RF may include a highly reflective metal material such as aluminum (Al). The thickness of the reflective film RF may be approximately 0.1 μm.

Alternatively, the reflective film RF may include a first layer and a second layer of M (M is an integer of 2 or more) pairs having different refractive indices to serve as Distributed Bragg Reflectors (DBR). In this case, M first layers and M second layers may be arranged alternately. The first layer and the second layer may be formed of an inorganic film, for example, silicon nitride (SiNₓ), silicon oxide (SiON), silicon oxide (SiOₓ), titanium oxide (TiOₓ), and/or aluminum oxide (AlOₓ).

The third capping layer CAP3 may be disposed on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ), silicon oxide (SiON), silicon oxide (SiOₓ), titanium oxide (TiOₓ), and/or aluminum oxide (AlOₓ). The first light conversion layer QDL1, the second light conversion layer QDL2, and the light transmission layer TPL may be encapsulated by the first capture layer CAP1, the second capping layer CAP2, and the third capping layer CAP3.

A fourth organic film 213 may be disposed on the third capping layer CAP3. A plurality of color filters CF1, CF2, and CF3 may be disposed on the fourth organic film 213. The plurality of color filters CF1, CF2, and CF3 may include first color filters CF1, second color filters CF2, and third color filters CF3.

The first color filter CF1 disposed in the first sub-pixel SPX1 may transmit the first light (light in the red wavelength band) and absorb or block the third light (light in the blue wavelength band). Therefore, the first color filter CF1 may transmit the first light (light in the red wavelength band) that has been converted by the first light conversion layer QDL1 from among the third light (light in the blue wavelength band) emitted from the light emitting element LE and absorb or block the third light (light in the blue wavelength band) that has not been converted by the first light conversion layer QDL1. Accordingly, the first sub-pixel SPX1 may emit the first light (light in the red wavelength band).

The second color filter CF2 disposed in the second sub-pixel SPX2 may transmit the second light (light in the green wavelength band) and absorb or block the third light (light in the blue wavelength band). Therefore, the second color filter CF2 may transmit the second light (light in the green wavelength band) that has been converted by the second light conversion layer QDL2 among the third light (light in the blue wavelength band) emitted from the light emitting element LE and absorb or block the third light (light in the blue wavelength band) that has not been converted by the second light conversion layer QDL2. Accordingly, the second sub-pixel SPX2 may emit the second light (light in the green wavelength band).

The third color filter CF3 disposed in the third sub-pixel SPX3 may transmit the third light (light in the blue wavelength band). Therefore, the third color filter CF3 may transmit the third light (light in the blue wavelength band) emitted from the light emitting element LE passing through the light transmission layer TPL. Accordingly, the third sub-pixel SPX3 may emit the third light (light in the blue wavelength band).

The first color filter CF1, the second color filter CF2, and the third color filter CF3 overlapping in the third direction DR3 may overlap with the light blocking layer BM in the third direction DR3.

A fifth organic film 214 may be disposed on the plurality of color filters CF1, CF2, and CF3 for planarization.

The fourth organic film 213 and the fifth organic film 214 may be formed from an acrylic resin, an epoxy resin, a phenolic resin, a polyamide resin, a polyimide resin, and/or the like.

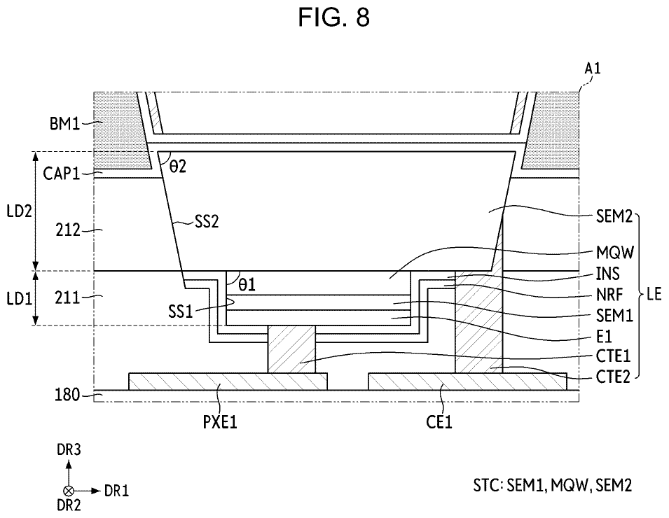

FIG. 8 is a cross-sectional view illustrating another example of the area A1 of FIG. 6 in detail.

The embodiment of FIG. 8 differs from the embodiment of FIG. 7 in that the first side surface SS1 of the first element rod LD1 has a first inclination angle θ1 that is substantially vertical (e.g., at a right angle). In FIG. 8, descriptions that overlap with the embodiments described with reference to FIGS. 6 and 7 will not be repeated, and differences from the embodiment of FIG. 7 will be mainly described.

Referring to FIG. 8, the first element rod LD1 may include a substantially vertical side surface. For example, the first side surface SS1 may include a first inclination angle θ1. The first inclination angle θ1 of the first side surface SS1 may be formed at 90 degrees, or may be 70 degrees or more and less than 90 degrees, as shown in FIG. 8. Therefore, the first side surface SS1 of the first element rod LD1 may be formed with a regular taper.

On the other hand, the second element rod LD2 may have a second inclination angle θ2. For example, the first inclination angle θ1 may be greater than the second inclination angle θ2.

The light emitting element may include substantially vertical sides. For example, the light emitting element LE may be patterned through vertical etching and may have a rectangular or square cross-sectional shape in which a width of the top surface and the width of the bottom surface are substantially the same. The height of the light emitting element LE may be about 5.5 μm but is not limited thereto.

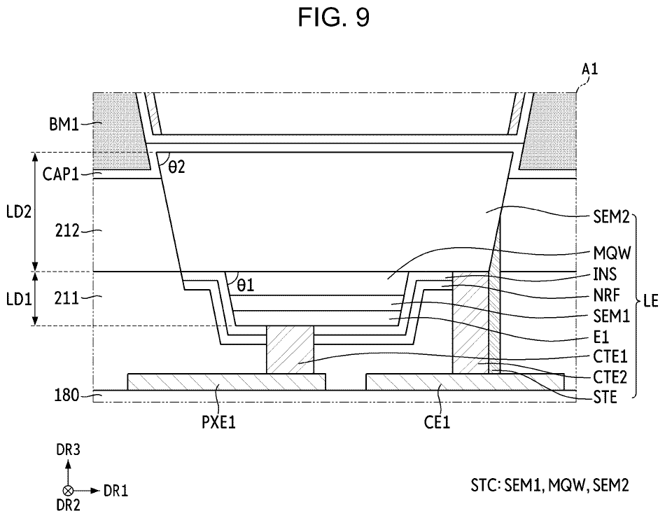

FIG. 9 is a cross-sectional view illustrating another example of the area A1 of FIG. 6 in detail.

The embodiment of FIG. 9 differs from the embodiment of FIG. 7 in that the light emitting element LE includes a support STE supporting the second contact electrode CTE2. In FIG. 9, descriptions that overlap with the embodiments described with reference to FIGS. 6 and 7 will not be repeated, and differences from the embodiment of FIG. 7 will be mainly described.

Referring to FIG. 9, a first contact electrode CTE1 is disposed on one side of the first element rod LD1.

One side of the second contact electrode CTE2 is disposed on one side of the second element rod LD2. The support STE is disposed on a portion of the side surface of the second element rod LD2 to support the second contact electrode CTE2.

The first contact electrode CTE1 and the second contact electrode CTE2 may be spaced (e.g., spaced apart) from each other in the first direction and/or the second direction DR2. The second contact electrode CTE2 and the support STE may be disposed to contact each other. The first contact electrode CTE1, the second contact electrode CTE2, and the support STE may be columnar in shape extending in the third direction DR3. One end of the first contact electrode CTE1, one end of the second contact electrode CTE2, and one end of the support STE are disposed on the same straight line.

On the plane, the area of the first contact electrode CTE1 may be equal to the sum of the area of the second contact electrode CTE2 and the area of the support STE. The second contact electrode CTE2 and the support STE may be combined to be referred to as a second pad electrode. Similarly, when the first contact electrode CTE1 is referred to as a first pad electrode, the area of the first pad electrode on the plane is equal to the area of the second pad electrode.

The first contact electrode CTE1 and the second contact electrode CTE2 may be formed of the same material. For example, the first contact electrode CTE1 and the second contact electrode CTE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO).

The second contact electrode CTE2 may be a metal having a higher conductivity than the support STE. On the other hand, the support STE may be formed as a single metal having a higher strength than the second contact electrode CTE2. Furthermore, the support STE may use a metal having a lower unit cost than the second contact electrode CTE.

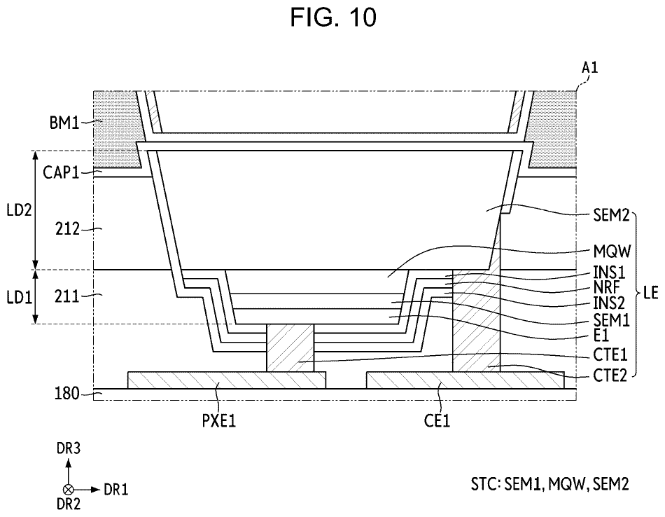

FIG. 10 is a cross-sectional view illustrating another example of the area A1 of FIG. 6 in detail.

The embodiment of FIG. 10 differs from the embodiment of FIG. 7 in that it further includes a protective film INS covering one side and side surface of the first element rod LD1 and the side surface of the second element rod LD2. In FIG. 10, the description overlapping with the embodiment described with reference to FIGS. 6 and 7 will not be repeated, and the description will be focused on the differences from the embodiment of FIG. 7.

Referring to FIG. 10, a first protective film INS1 may be disposed on the bottom surface and side surface of the conductive layer E1, the side surface of the first semiconductor layer SEM1, and the side surface of the active layer MQW. The first protective film INS1 has an opening at a position overlapping the first contact electrode CTE1 on the first element rod LD1. The first protective film INS1 is referred to as the first protective film INS1 to facilitate distinction from the second protective film INS2 disposed on the outermost layer of the light emitting element LE, and the second protective film INS2 disposed on the outermost layer.

The first protective film INS1 may extend from the side of the first element rod LD1 to one side of the second element rod LD2. The first protective film INS1 may not be disposed on the side of the second element rod LD2. The first protective film INS1 has an opening at a position overlapping the second contact electrode CTE2 on the second element rod LD2.

A reflective film NRF may be disposed on the first protective film INS1. The reflective film NRF may be disposed on the bottom surface and side surface of the conductive layer E1, the side surface of the first semiconductor layer SEM1, and the side surface of the active layer MQW on the first protective film INS1. Further, the reflective film NRF may extend from the side of the first element rod LD1 to one side of the second element rod LD2. The reflective film NRF may not be disposed on the side of the second element rod LD2.

The reflective film NRF may extend from the side of the first element rod LD1 to one side of the second element rod LD2. The reflective film NRF may not be disposed on the side of the second element rod LD2. The reflective film NRF may be a Distributed Bragg Reflector (DBR) including a first layer and a second layer of M pairs (M is an integer greater than or equal to 2) having different refractive indices.

The reflective film NRF has an opening at a position overlapping an opening of the first protective film INS1.

The second protective film INS2 is around (e.g., surrounds) one side and side surface of the first element rod LD1 and the side surface of the second element rod LD2 on the reflective film NRF. For example, the second protective film INS2 may be disposed on the bottom surface and side surface of the conductive layer E1, the side surface of the first semiconductor layer SEM1, the side surface of the active layer MQW, and the side surface of the second semiconductor layer SEM2 on the reflective film NRF. The second protective film INS2 has an opening at a position overlapping with an opening of the reflective film NRF.

The first protective film INS1 and the second protective film INS2 may be formed of an inorganic film, for example, silicon nitride (SiNₓ), silicon oxide (SiON), silicon oxide (SiOₓ), titanium oxide (TiOₓ), and/or aluminum oxide (AlOₓ).

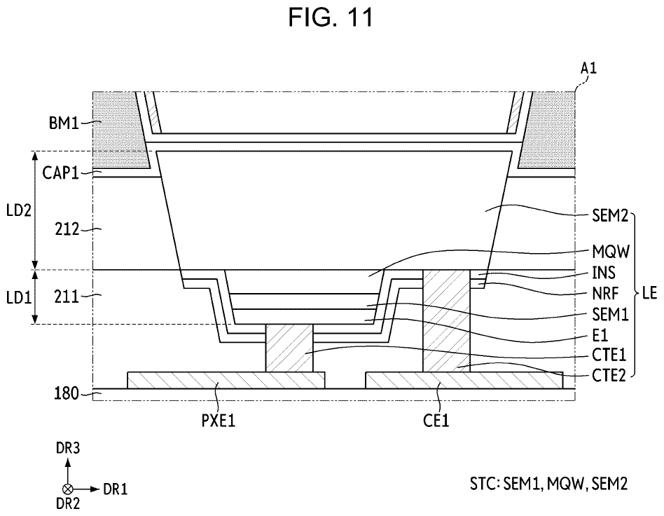

FIG. 11 is a cross-sectional view illustrating another example of the area A1 of FIG. 6 in detail.

The embodiment of FIG. 11 differs from the embodiment of FIG. 7 in that the second contact electrode CTE2 is disposed on one surface of the second element rod LD2 and not on the side surface of the second element rod LD2. In FIG. 11, the description overlapping with the embodiment described with reference to FIGS. 6 and 7 will not be repeated, and the description will be focused on the differences from the embodiment of FIG. 7.

Assuming that the second element rod LD2 of FIG. 11 has the same size and shape as the second element rod LD2 of FIG. 7, it can be seen that the width of the first element rod LD1 is narrower compared to the case where the second contact electrode CTE2 is disposed on the side of the second element rod LD2 as in FIG. 7 when the second contact electrode CTE2 is disposed on the second element rod LD2 as in FIG. 11.

Referring to the embodiments of FIGS. 7 and 10, it may be confirmed that the second contact electrode CTE2 is disposed on the side of the second element rod LD2 to sufficiently secure the width of the first element rod LD1, and accordingly, the width of the active layer MQW may be secured.

For example, comparing the embodiments of FIGS. 11 and 7, the area of the active layer MQW in the embodiment of FIG. 7 may be expanded by about 2 μm to about 3 μm. When the size of the light emitting element is about 10 μm×about 25 μm, the area of the active layer MQW may be expanded by about 15 to 20%, and when the size of the light emitting element is about 7 μm×about 15 μm, the area of the active layer MQW may be expanded by about 25 to 30%.

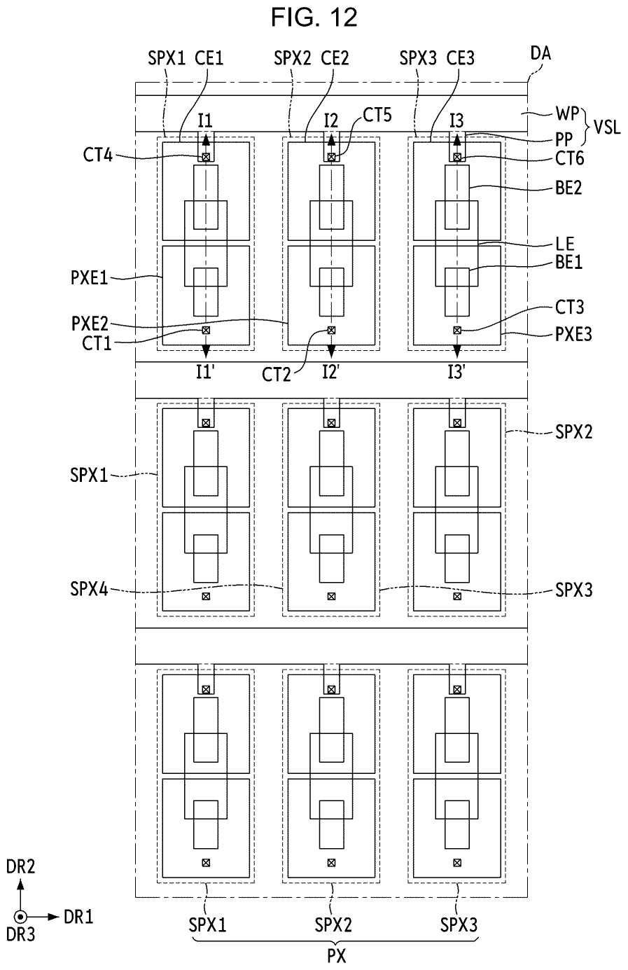

FIG. 12 is a layout drawing illustrating pixels of a display area according to one or more embodiments.

The embodiment of FIG. 12 differs from the embodiment of FIG. 5 in that the second power supply line VSL connected to the common electrodes CE1, CE2, and CE3 is disposed. In the embodiment of FIG. 12, the description overlapping with the embodiment of FIG. 5 is omitted.

Referring to FIG. 12, a first common electrode CE1 may be connected to the second power supply line VSL to which a second driving voltage VSS is applied through a first common connection hole CT4. A second common electrode CE2 may be connected to the second power supply line VSL through a second common connection hole CT5. A third common electrode CE3 may be connected to the second power supply line VSL through a third common connection hole CT6. Therefore, the second driving voltage VSS may be applied to each of the common electrodes CE1, CE2, and CE3.

A first connection electrode BE1 is connected to the light emitting element LE and the pixel electrode PXE1, PXE2, and PXE3. The first connection electrode BE1 may overlap at least a portion of the pixel electrode PXE1, PXE2, and PXE3 and at least a portion of the light emitting element LE.

A second connection electrode BE2 may be connected to the light emitting element LE and the common electrode CE1, CE2, and CE3. The second connection electrode BE2 may overlap at least a portion of the common electrode CE1, CE2, and CE3 and at least a portion of the light emitting element LE.

Each of the second power supply lines VSL may include a line portion WP extending in the first direction DR1 and a protrusion portion PP protruding from the line portion WP in the second direction DR2 and overlapping with a common connection hole CT4, CT5, CT6.

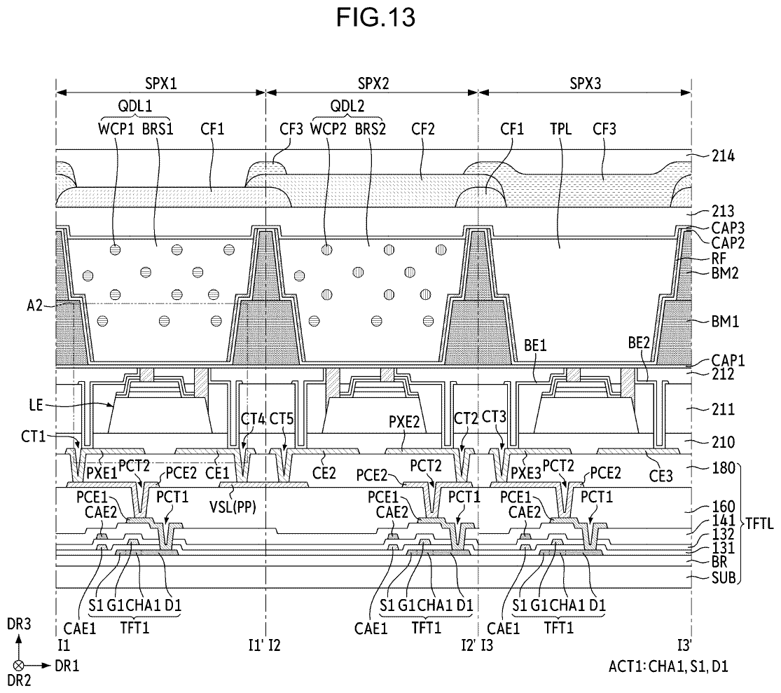

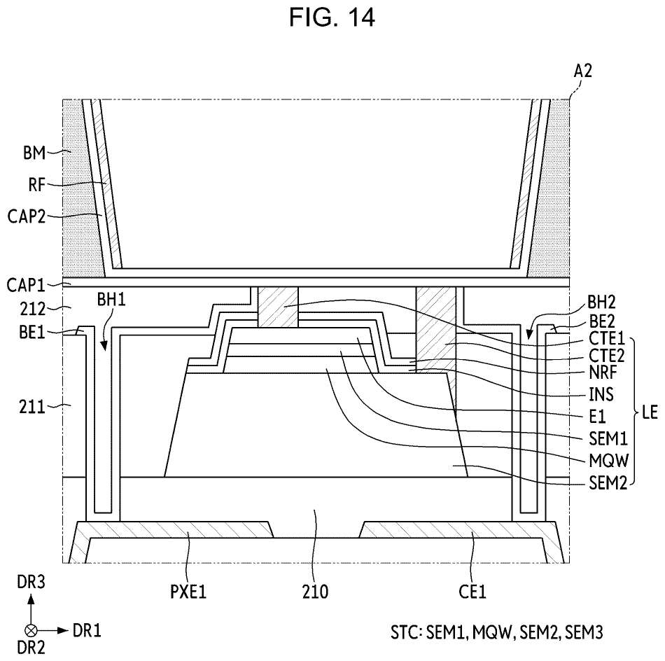

FIG. 13 is a cross-sectional view illustrating another example of a cross-section of a display panel corresponding to the lines I1-I1′, I2-I2′, and I3-I3′ of FIG. 12. FIG. 14 is a cross-sectional view illustrating one example of an area A2 of FIG. 13 in detail.

The embodiments of FIGS. 13 and 14 differ from the embodiments of FIGS. 6 and 7 in that the light emitting element LE is a lateral type micro LED in which both the first contact electrode CTE1 and the second contact electrode CTE2 protrude from the top surface of the light emitting element LE, so that current flows in the lateral direction. In the embodiments of FIGS. 13 and 14, descriptions that overlap with the embodiments of FIGS. 6 and 7 will not be repeated, and differences from the embodiments of FIGS. 6 and 7 will be mainly described.

Referring to FIGS. 13 and 14, a pixel electrode layer including pixel electrodes PXE1, PXE2, and PXE3 and common electrodes CE1, CE2, and CE3 may be disposed on the second planarization film 180. The pixel electrodes PXE1, PXE2, and PXE3 and the common electrodes CE1, CE2, and CE3 may be spaced (e.g., spaced apart) from each other.

The pixel electrodes PXE1, PXE2, and PXE3 may be connected to a second source connection electrode PCE2 through pixel connection holes CE1, CE2, and CE3 penetrating the second planarization film 180. The pixel electrodes PXE1, PXE2, and PXE3 may be connected to a first source area S1 or a first drain area D1 of the thin film transistor TFT1 through the first source connection electrode PCE1 and the second source connection electrode PCE2. Therefore, a voltage controlled by the thin film transistor TFT1 may be applied to the pixel electrodes PXE1, PXE2, and PXE3.

The common electrodes CE1, CE2, and CE3 may be connected to the second power supply line VSL through the common connection holes CT4, CT5, and CT6 penetrating the second planarization film 180. Therefore, a second driving voltage (VSS in FIG. 3) may be applied to the common electrodes CE1, CE2, and CE3.

When the pixel electrode layer is made of a metal material with high reflectivity, light emitted from the active layer MQW of the light emitting element LE propagates downwardly toward the light emitting element LE. The light may be reflected from the pixel electrodes PXE1, PXE2, and PXE3 and the common electrodes CE1, CE2, and CE3 and propagate upward toward the light emitting element LE. Therefore, because the light loss of the light emitting element LE may be reduced, the light efficiency of the light emitting element LE may be increased.

An organic layer 210 may be disposed on the pixel electrodes PXE1, PXE2, and PXE3 and the common electrodes CE1, CE2, and CE3 of each of the sub-pixels SPX1, SPX2, and SPX3. The organic layer 210 temporarily fixes or adheres the light emitting element LE in the process of transferring the light emitting element LE to the display panel 100.

The light emitting element LE of each of the sub-pixels SPX1, SPX2, and SPX3 may be disposed on the organic layer 210.

The connection holes BH1 and BH2 penetrate the organic layer 210 and the second organic film 211 to expose at least a portion of the pixel electrodes PXE1, PXE2, and PXE3 and the common electrodes CE1, CE2, and CE3.

The first connection electrode BE1 connects the first contact electrode CTE1 of the light emitting element LE and the pixel electrode PXE1, PXE2, and PXE3. The first connection electrode BE1 may be connected to the pixel electrode PXE1, PXE2, and PXE3 through the first connection hole BH1 penetrating the organic layer 210 and the second organic film 211. For example, the first connection electrode BE1 may contact the pixel electrode PXE1, PXE2, and PXE3 exposed through the first connection hole BH1.

The second connection electrode BE2 connects the second contact electrode CTE2 of the light emitting element LE and the common electrode CE1, CE2, and CE3. The second connection electrode BE2 may be connected to the common electrode CE1, CE2, and CE3 through a second connection hole BH2 penetrating the organic layer 210 and the second organic film 211. For example, the second connection electrode BE2 may contact the common electrode CE1, CE2, and CE3 exposed through the second connection hole BH2.

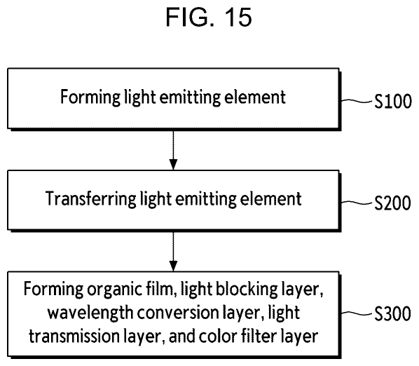

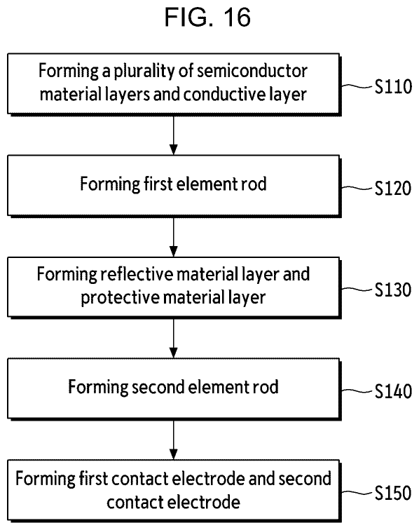

FIG. 15 is a flowchart illustrating a method for manufacturing a display device according to one or more embodiments. FIG. 16 is a flowchart illustrating a method for manufacturing a light emitting element of step S100 of FIG. 15.

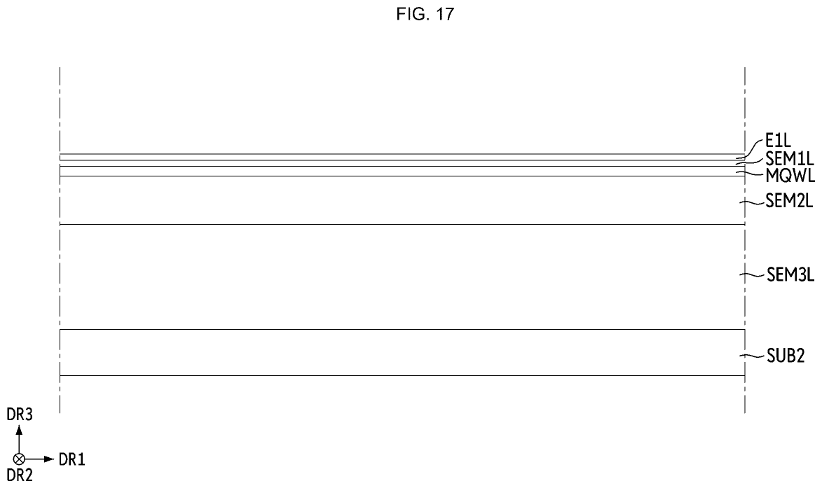

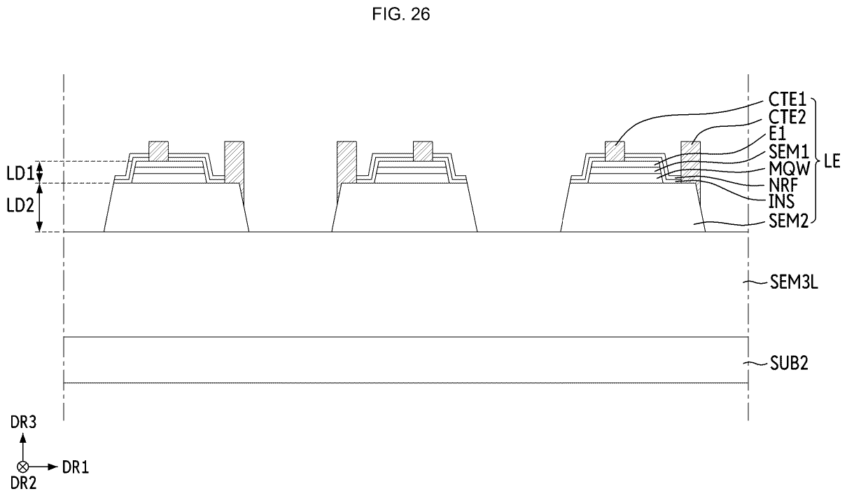

FIGS. 17-28 are example drawings to illustrate a method for manufacturing a display device. The light emitting elements LE described in FIGS. 17-28 may correspond to the light emitting elements LE described with reference to FIG. 7.

Referring to FIG. 15, a method for manufacturing a display device may include a step of forming a light emitting element LE S100, a step of transferring a light emitting element S200, and a step of forming an organic film, a light blocking layer, a wavelength conversion layer, a light transmission layer, and a color filter layer S300.

First, the step of forming the light emitting element LE of S100 of FIG. 15 will be described in detail with respect to FIG. 16 along with FIGS. 17-20.

First, a plurality of semiconductor material layers SEM3L, SEM2L, MQWL, and SEM1L, and a conductive layer E1L are formed on a growth substrate SUB2. (S110 of FIG. 16)

First, a growth substrate SUB2 is prepared. The growth substrate SUB2 may be a sapphire substrate Al₂O₃ and/or a transparent silicon wafer including silicon. However, it is not limited thereto, and in one or more embodiments, a case in which the growth substrate SUB2 is a sapphire substrate is described as an example.

A plurality of semiconductor material layers SEM3L, SEM2L, MQWL, and SEM1L are formed on the growth substrate SUB2. The plurality of semiconductor material layers grown by the epitaxial method may be formed by growing a seed crystal. Methods for forming semiconductor material layers include electron beam deposition, physical vapor deposition (PVD), chemical vapor deposition (CVD), and plasma laser deposition (PLD), dual-type thermal evaporation, sputtering, metal organic chemical vapor deposition (MOCVD), and/or the like, and preferably formed by metal organic chemical vapor deposition (MOCVD). However, it is not limited thereto.

A precursor material for forming the plurality of semiconductor material layers is not particularly limited within the range that may be conventionally selected for forming the subject material. In one example, the precursor material may be a metal precursor including an alkyl group such as a methyl group or an ethyl group. For example, it may be a compound such as trimethyl gallium (Ga(CH₃)₃), trimethyl aluminum (Al(CH₃)₃), triethyl phosphate ((C₂H₅)₃PO₄), but are not limited thereto.

Specifically, a third semiconductor material layer SEM3L is formed on the growth substrate SUB2. In the drawing, the third semiconductor layer SEM3 is illustrated as being laminated in one layer but is not limited thereto, and a plurality of layers may be formed. The third semiconductor material layer SEM3L may be disposed to reduce the lattice constant difference between the second semiconductor material layer SEM2L and the growth substrate SUB2. In one example, the third semiconductor material layer SEM3L may include an undoped semiconductor and may be a material that is not doped as n-type or p-type dopant. In one or more embodiments, the third semiconductor material layer SEM3L may be undoped InAlGaN, GaN, AlGaN, InGaN, AlN, and/or InN but is not limited thereto.

The second semiconductor material layer SEM2L, the active material layer MQWL, and the first semiconductor material layer SEM1L are sequentially formed on the third semiconductor material layer SEM3L using the above-described method.

Next, a conductive layer E1L is deposited on the semiconductor material layer SEM3L, SEM2L, MQWL, and SEM1L. The conductive layer E1L may include, but not limited to, molybdenum (Mo), aluminum (Al), chromium (Cr), gold (Au), titanium (Ti), nickel (Ni), neodymium (Nd), and/or copper (Cu).

Next, a portion of the conductive layer E1L, the first semiconductor material layer SEM1L, and the active material layer MQWL are etched using a hard mask HM to form a first element rod LD1. (S120 of FIG. 16)

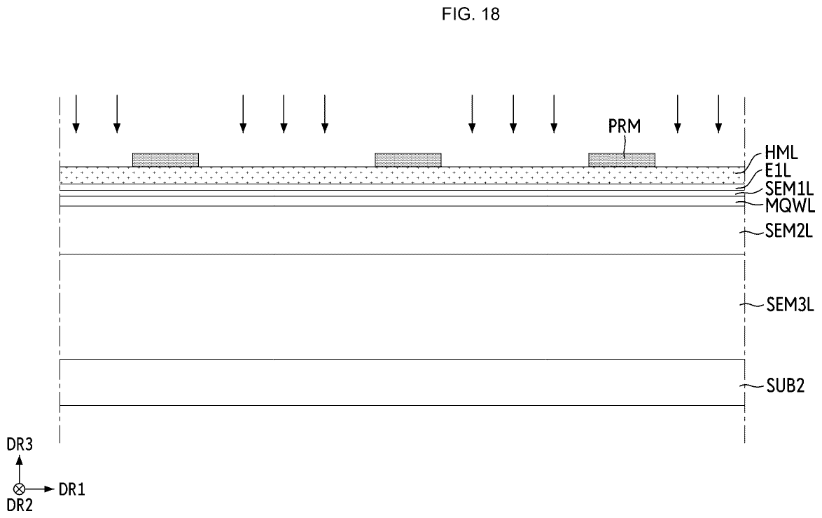

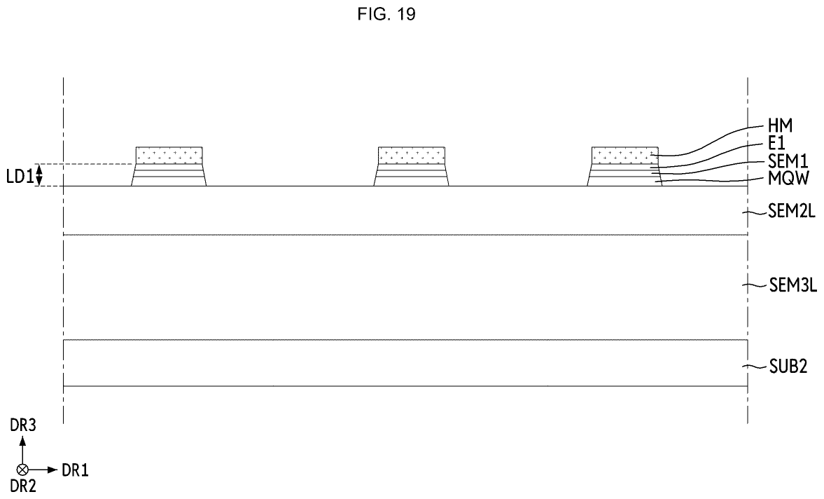

For example, as shown in FIG. 18 and FIG. 19, a hard mask material layer HML is formed on the conductive layer E1L. The hard mask material layer HML may be formed of silicon oxide (SiOx). The hard mask HM formed accordingly is also formed of silicon oxide (SiOx). A patterned photoresist mask PRM is formed on the hard mask material layer HML. Photoresist is a photosensitive material and is an organic solvent made of resin and a photosensitive agent. Therefore, the photoresist mask PRM is also formed of a photosensitive material.

Thereafter, the hard mask material layer HML is patterned through a dry etching process using a patterned photoresist mask PRM as a mask. The hard mask material layer HML in an area that does not overlap with the patterned photoresist mask PRM by the dry etching process is etched to pattern the hard mask HM. Then, the photoresist mask pattern PRM is removed by ashing. Afterward, the conductive layer E1L, the first semiconductor material layer SEM1L, and the active material layer MQWL are etched using the patterned hard mask HM as a mask to form a first element rod LD1. In dry etching, as the depth of etching increases, the process time increases, and the plasma exposure time of the semiconductor material layer increases, so damage to the active layer may increase. Therefore, in one or more embodiments, the entire semiconductor material layer is not etched in one process during the dry etching, but only a portion of the entire semiconductor material layer is etched. In this way, when etching only some semiconductor material layers compared to etching the entire semiconductor material layer, the etching time is reduced, which reduces or minimizes damage to the active material layer MQWL that may occur during the etching process.

Next, a protective material layer INSL and a reflective material layer NRFL are formed. (S130 of FIG. 16)

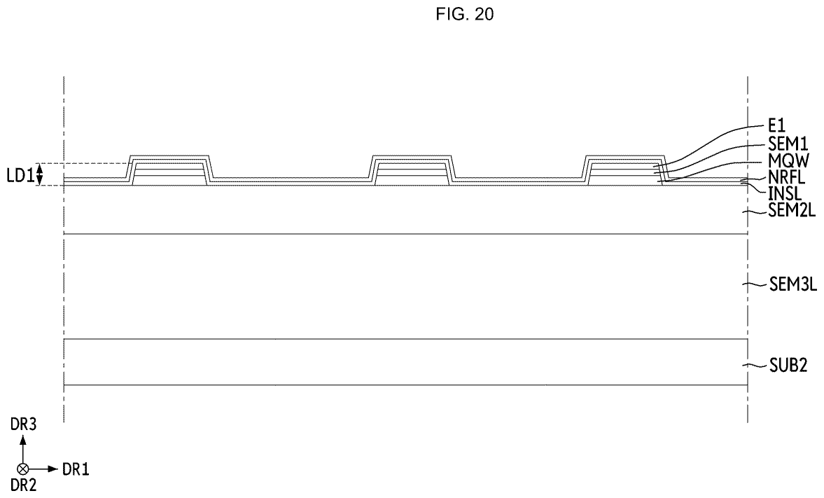

For example, referring to FIG. 20, a protective material layer INSL is formed on the entire surface of the growth substrate SUB2 to cover the entire first element rod LD1.

Thereafter, a reflective material layer NRFL is formed on the entire surface of the growth substrate SUB2 to cover the entire protective material layer INSL.

Next, a second element rod LD2 is formed. (S140 of FIG. 16)

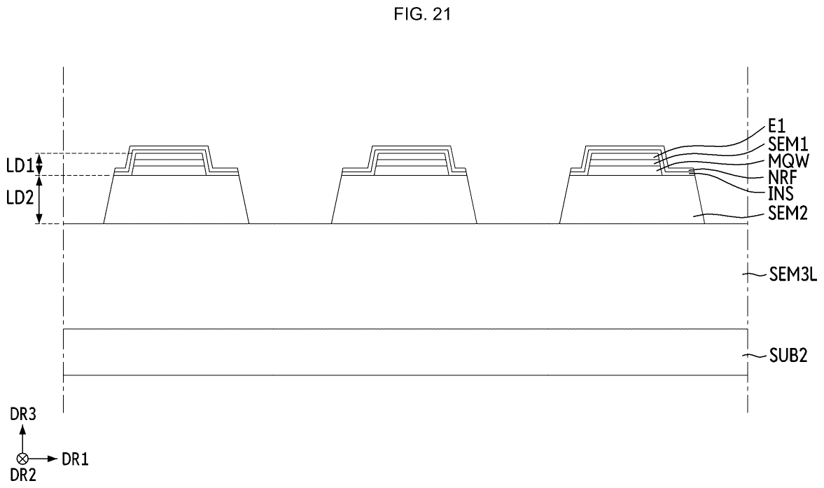

For example, referring to FIG. 21, a mask overlapping the first element rod LD1 is formed, and the second semiconductor material layer SEM2L is etched to form the second element rod LD2.

Next, the first contact electrode CTE1 and the second contact electrode CTE2 are formed. (S150 of FIG. 16)

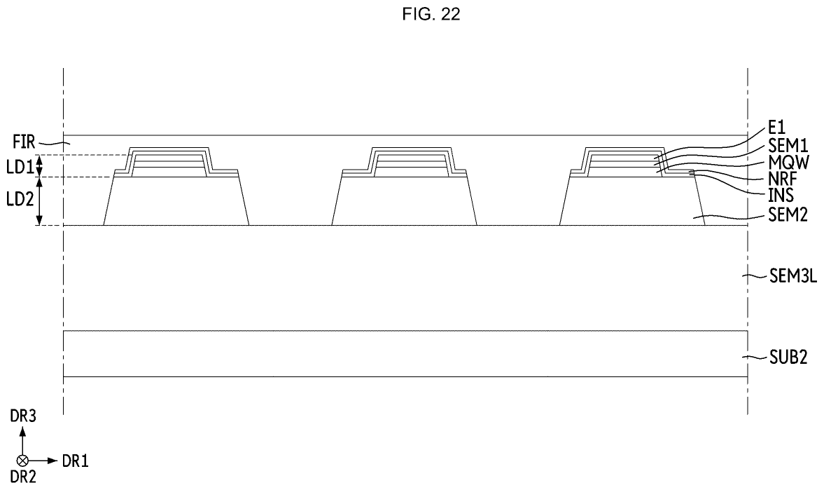

For example, referring to FIG. 22, a filler FIR is filled between the first element rod LD1 and the second element rod LD2. The filler FIR may be, for example, a photoresist but is not limited thereto.

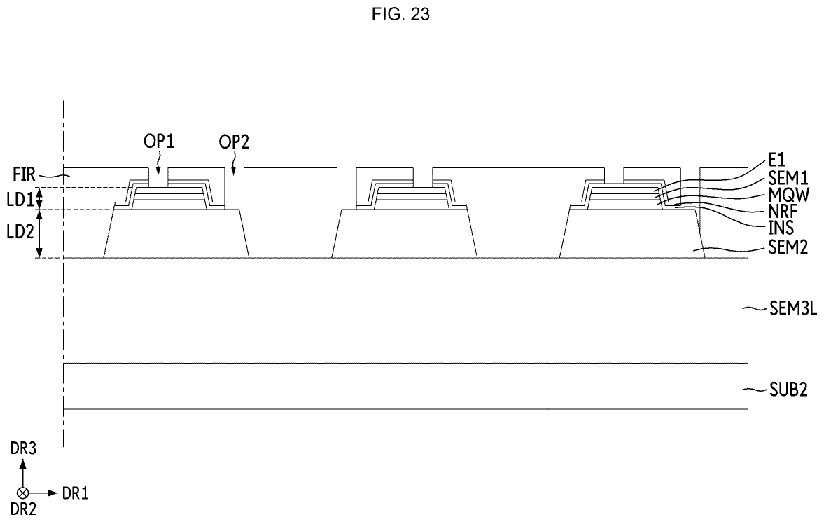

Then, referring to FIG. 23, a first opening OP1 exposing the first element rod LD1 and a second opening OP2 exposing at least a portion of the top surface and side surface of the second element rod LD2 are formed using a mask.

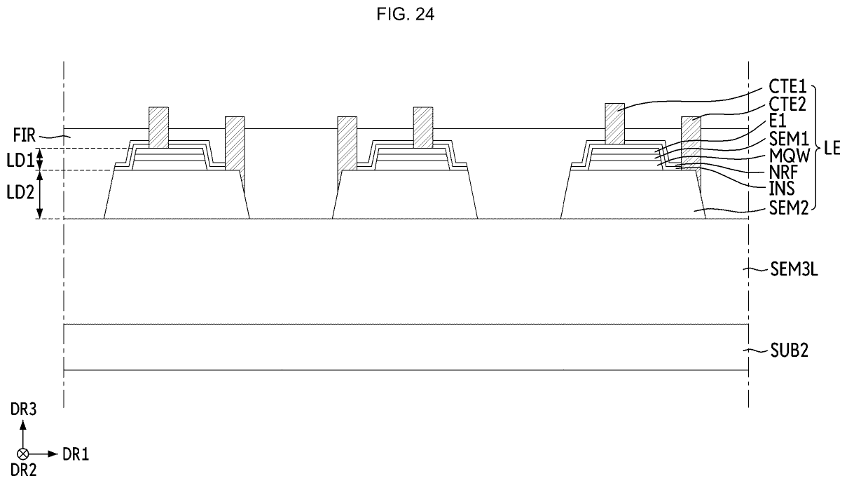

As shown in FIG. 24, by filling the first opening OP1 and the second opening OP2 with an electrode material layer, a first contact electrode CTE1 is formed in the first opening OP1 and a second contact electrode CTE2 is formed in the second opening OP2.

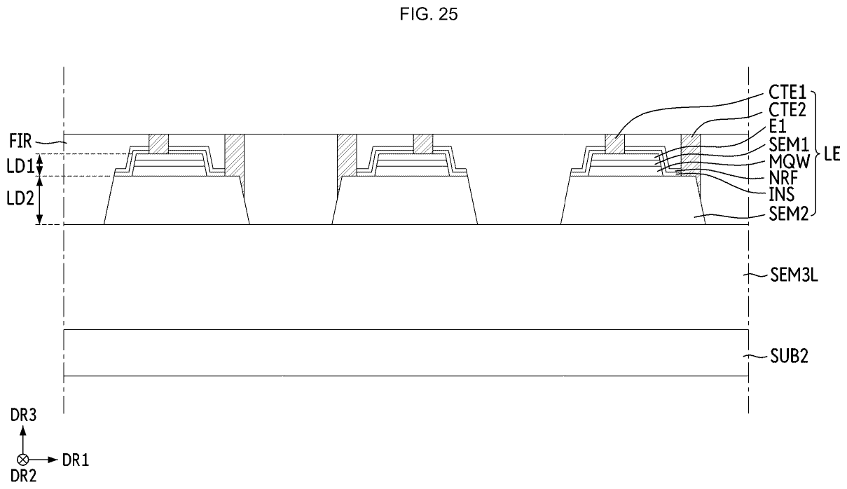

As shown in FIG. 25, the top surfaces of the first contact electrode CTE1 and the second contact electrode CTE2 may be planarized by wet etching. As a result, the top surface of the first contact electrode CTE1 and the top surface of the second contact electrode CTE2 may be disposed in a straight line. That is, the heights of the top surface of the first contact electrode CTE1 and the top surface of the second contact electrode CTE2 do not have a step.

As shown in FIG. 25, the filler is removed by a method such as an ashing process.

In this way, the light emitting element LE on the growth substrate SUB2 is transferred onto the substrate SUB. (S200 of FIG. 15).

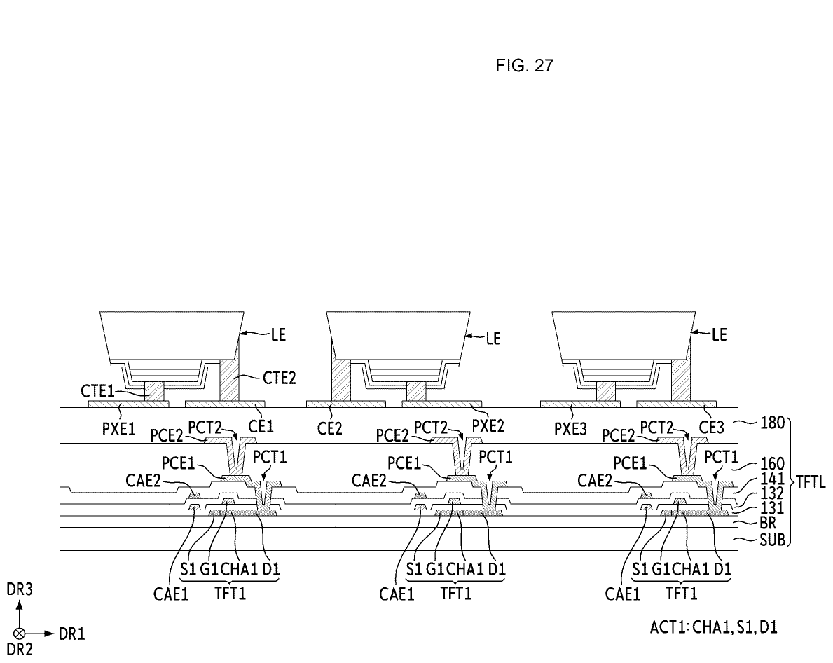

For example, referring to FIG. 27, the growth substrate SUB2 is disposed on the substrate SUB so that the light emitting element LE on the growth substrate SUB2 faces the pixel electrodes PXE1, PXE2, and PXE3 and the common electrode CE1, CE2, and CE3. Then, the first contact electrode CTE1 and the second contact electrode CTE2 of the light emitting element LE are bonded on the pixel electrodes PXE1, PXE2, and PXE3 and the common electrode CE1, CE2, and CE3. The bonding of the first contact electrode CTE1 and the second contact electrode CTE2 to the pixel electrodes PXE1, PXE2, and PXE3 and the common electrode CE1, CE2, and CE3 may be performed by a conventionally known process, for example, a eutectic process.

Then, the growth substrate SUB2 may be separated from the light emitting element LE and removed. For example, considering the spacing between the plurality of light emitting elements LE disposed on the growth substrate SUB2, a laser is irradiated on the desired light emitting element LE. The light emitting element LE irradiated with the laser may be separated from the growth substrate SUB2.

In one or more embodiments, for the convenience of explanation in this specification, the light emitting element LE on the growth substrate SUB2 is directly transferred onto the substrate SUB, but it is not limited thereto, and may be transferred through a plurality of relay substrates, etc.

Next, an organic film, a light blocking layer, a wavelength conversion layer, a light transmission layer, and a color filter layer are sequentially formed. (S300 of FIG. 15)

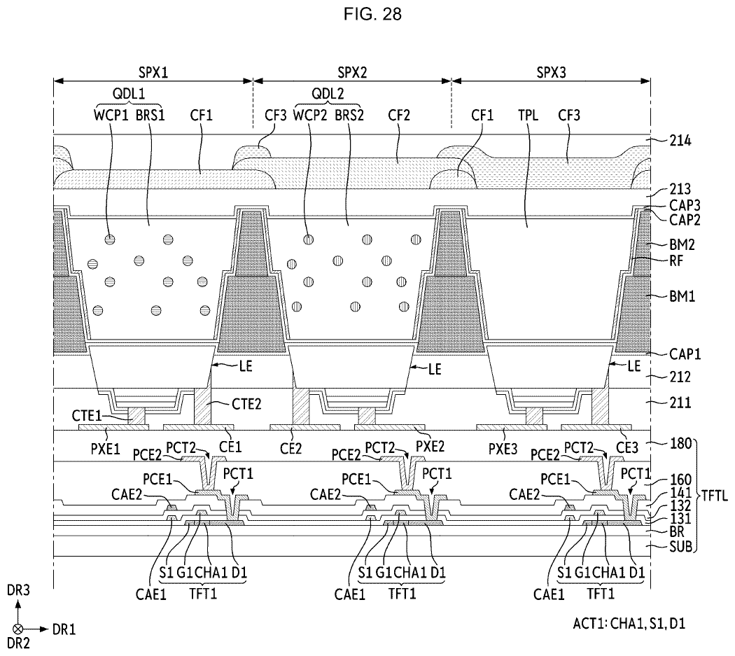

Referring to FIG. 28, a second organic film 211 and a third organic film 212 are formed to fix the light emitting elements LE and flatten the steps caused by the light emitting elements LE.

Then, a first capping layer CAP1 is formed on the third organic film 212 and the light emitting elements LE, and a first light blocking layer BM1 and a second light blocking layer BM2 are formed on the first capping layer CAP1 so as not to overlap with the light emitting elements LE in the third direction DR. Then, a second capping layer CAP2 covering the first light blocking layer BM1, the second light blocking layer BM2, and the first capping layer CAP1 is formed. Then, a reflective film RF covering the second capping layer CAP2 disposed on the first light blocking layer BM1 and the second light blocking layer BM2 is formed.

Then, a first light conversion layer QDL1 is formed on each of the first sub-pixels SPX1, a second light conversion layer QDL2 is formed on each of the second sub-pixels SPX2, and a light transmission layer TPL is formed on each of the third sub-pixels SPX3. Then, a third capping layer CAP3 is formed covering the first light conversion layers QDL1, the second light conversion layers QDL2, and the light transmission layers TPL. Then, a fourth organic film 213 is formed on the third capping layer CAP3.

Then, a first color filter CF1 is formed on the fourth organic film 213 overlapping the first light conversion layers QDL1 in the third direction DR3, a second color filter CF2 is formed on the fourth organic film 213 overlapping the second light conversion layers QDL2 in the third direction DR3, and a third color filter CF3 is formed on the fourth organic film 213 overlapping the light transmission layers TPL in the third direction DR3. The first color filter CF1, the second color filter CF2, and the third color filter CF3 may all be formed in the area overlapping the first light blocking layer BM1 and the second light blocking layer BM2 in the third direction DR3.

Then, a fifth organic film 214 is formed on the first color filter CF1, the second color filter CF2, and the third color filter CF3.

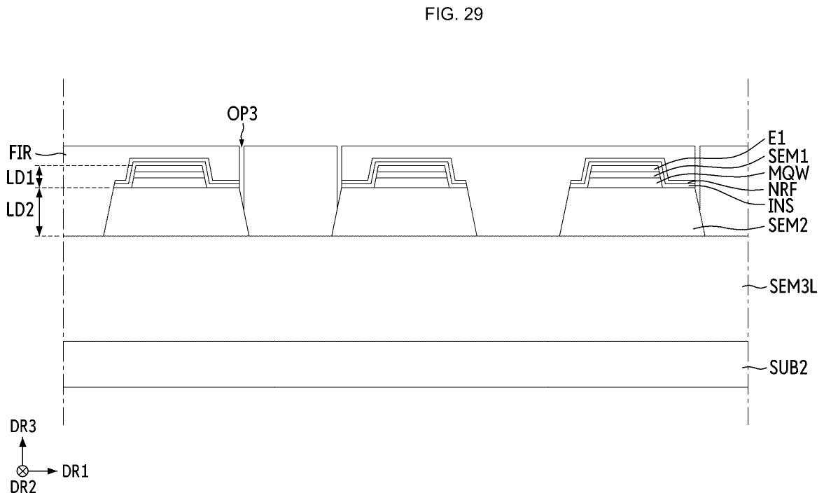

FIGS. 29-32 are example drawings to illustrate step S150 of FIG. 16 according to one or more other embodiments.

The light emitting element LE described in FIGS. 29-32 may correspond to the light emitting element LE described with reference to FIG. 7.

As described in FIG. 22, after filling the filler FIR between the first element rod LD1 and the second element rod LD2, a third opening OP3 is formed using a mask with reference to FIG. 29 to expose a portion of a side surface that is in contact with the top surface of the second element rod LD2.

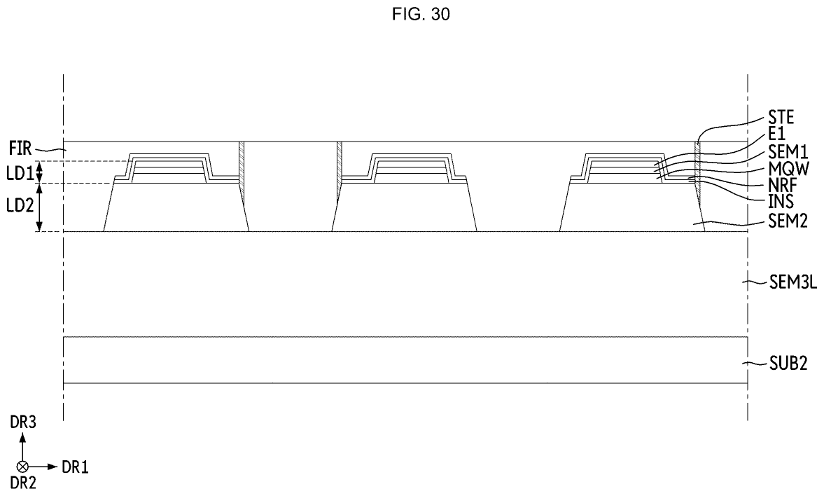

Reference to FIG. 30, a support STE is formed in the third opening OP3 by filling a support material layer.

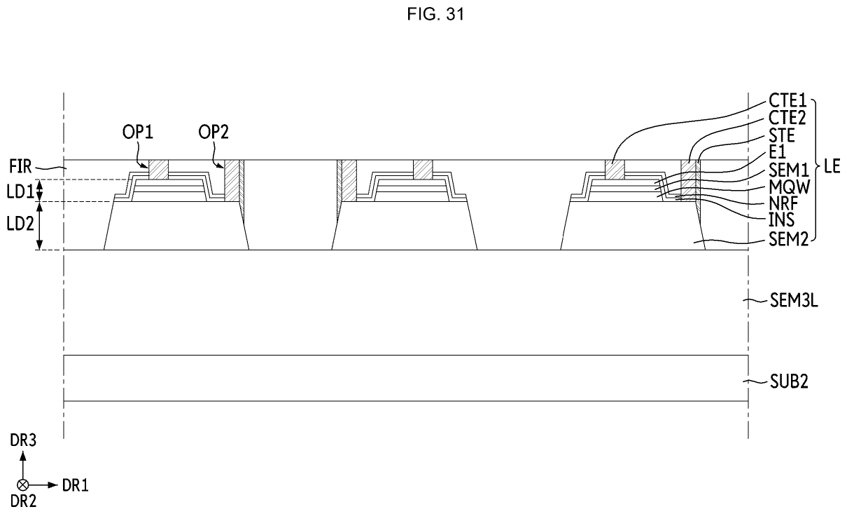

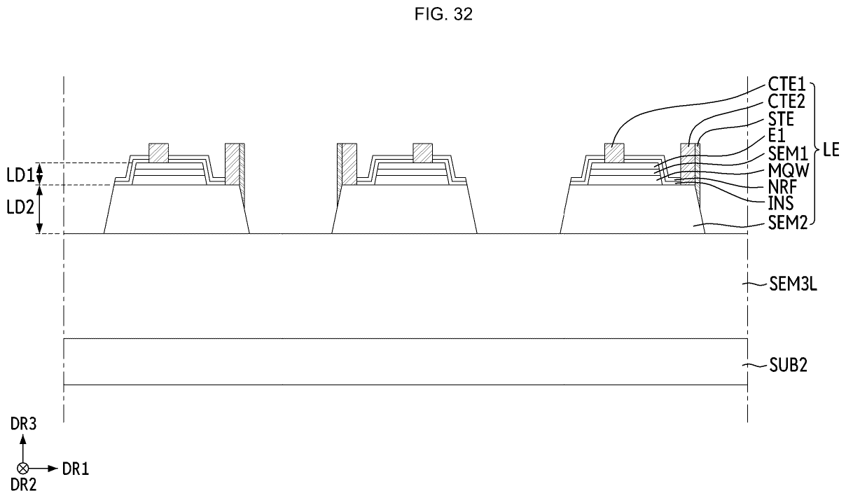

Reference to FIGS. 31 and 32, a first opening OP1 that exposes the first element rod LD1 and a second opening OP2 that exposes the top surface of the second element rod LD2 are formed using a mask. Then, by filling the first opening OP1 and the second opening OP2 with an electrode material layer, the first contact electrode CTE1 is formed in the first opening OP1 and the second contact electrode CTE2 is formed in the second opening OP2.

In this way, the second contact electrode CTE2 may be stably formed by first forming the support STE on the side of the second element rod LD2.

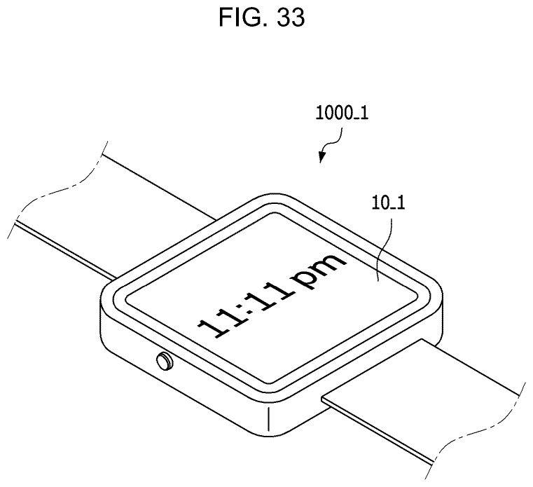

FIG. 33 is an example view of a smart watch including a display device according to one or more embodiments.

Referring to FIG. 33, a display device 10_1 according to one or more embodiments may be applied to a smart watch 1000_1 which is one of smart devices.

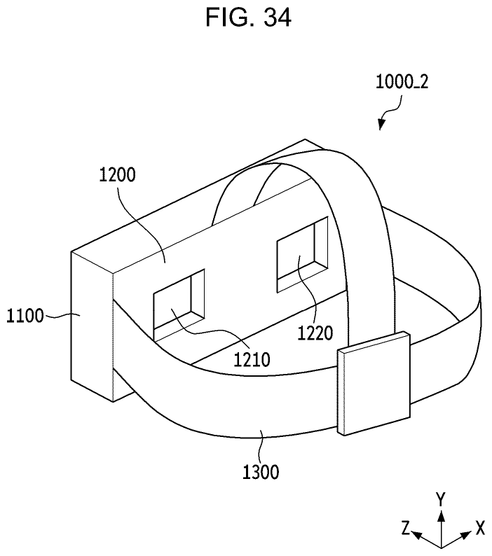

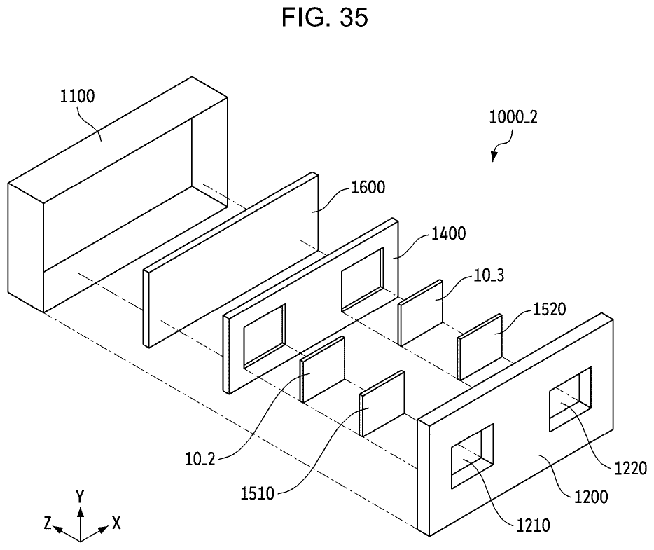

FIGS. 34 and 35 are example views of a virtual reality (VR) device including a display device according to one or more embodiments.

Referring to FIGS. 34 and 35, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 34 and 35, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

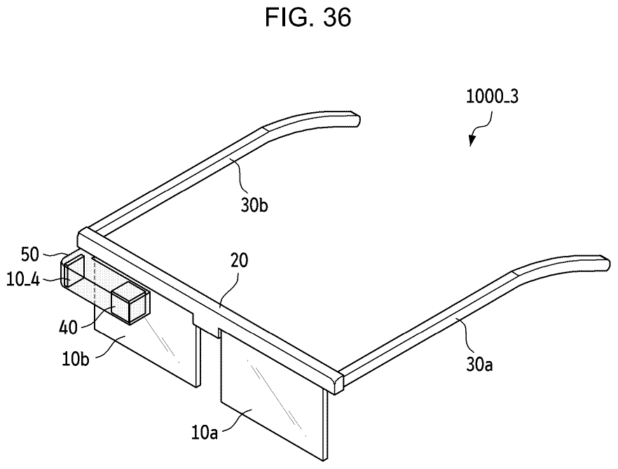

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 36 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 36 is an example view of a VR device including a display device according to one or more embodiments. FIG. 36 illustrates a VR device 1000_3 to which a display device 10_4 according to one or more embodiments has been applied.

Referring to FIG. 36, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 36, a case where the VR device 1000_3 is a glasses-type display device including the eyeglass frame legs 30a and 30b is illustrated as an example. That is, the VR device 1000_3 according to the embodiment is not limited to the one illustrated in FIG. 35 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 36, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

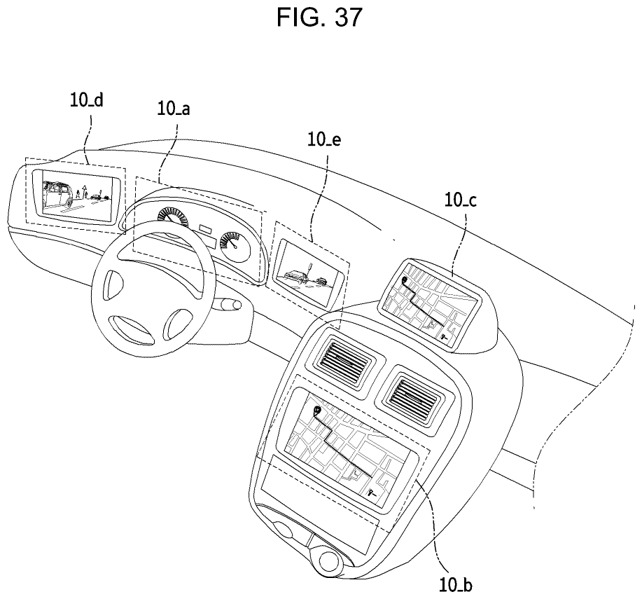

FIG. 37 is an example view illustrating a vehicle instrument cluster and center fascia including display devices according to one or more embodiments. FIG. 37 illustrates a vehicle to which display devices 10_a through 10_e according to one or more embodiments have been applied.

Referring to FIG. 37, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

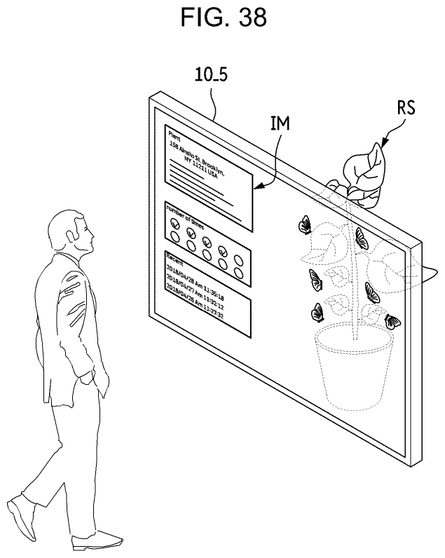

FIG. 38 is an example view of a transparent display device including a display device according to one or more embodiments.

Referring to FIG. 38, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a pixel electrode and a common electrode spaced from each other on the substrate; and
a light emitting element on the pixel electrode and the common electrode,
wherein the comprises:
a first element rod comprising a first semiconductor layer and an active layer that are sequentially stacked, and a side surface having a first inclination angle;
a second element rod comprising a second semiconductor layer, and a side surface having a second inclination angle;
a first contact electrode on the first element rod; and
a second contact electrode having one surface on one surface of the second element rod.

2. The display device of claim 1, wherein the one surface of the second contact electrode are arranged on a portion of the side surface of the second element rod.

3. The display device of claim 2, wherein the first contact electrode and the second contact electrode have a columnar shape,
wherein one end of the first contact electrode and one end of the second contact electrode are arranged in a straight line on a plane.

4. The display device of claim 2, wherein the second inclination angle is smaller than the first inclination angle.

5. The display device of claim 4, wherein the first element rod is on the second element rod,
wherein a width of the first element rod is smaller than a width of the second element rod at a boundary surface of the first element rod and the second element rod.

6. The display device of claim 5, the light emitting element further comprising a protective film and a reflective film sequentially located on one side and the side surface of the first element rod and a top surface of the second element rod exposed by the first element rod and having an opening in an area overlapping the first contact electrode and the second contact electrode.

7. The display device of claim 6, wherein the reflective film is a distributed Bragg reflector comprising a first layer and a second layer having different refractive indices.

8. The display device of claim 2, the light emitting element further comprises a support on a side of the second element rod and supporting the second contact electrode.

9. The display device of claim 8, wherein the second contact electrode and the support comprise different materials.

10. The display device of claim 8, wherein the second contact electrode has higher conductivity than the support, and wherein the support has higher strength than the second contact electrode.

11. The display device of claim 10, wherein the first contact electrode, the second contact electrode, and the support have a columnar shape,
wherein one end of the first contact electrode, one end of the second contact electrode, and one end the support are in a straight line on a plane,
wherein an area at the one end of the first contact electrode is equal to a sum of an area at the one end of the second contact electrode and an area at the one end of the support.

12. The display device of claim 11, further comprising a first connection electrode connecting the first contact electrode and the pixel electrode and a second connection electrode connecting the second contact electrode and the common electrode.

13. The display device of claim 12, further comprising an organic layer between the light emitting element and the pixel electrode and the common electrode.

14. A manufacturing method of a display device comprising:
forming a light emitting element on a growth substrate; and
transferring the light emitting element onto a substrate,
wherein the forming the light emitting element comprises:
forming a first semiconductor material layer, an active material layer, and a second semiconductor material layer on the growth substrate;
etching a portion of the first semiconductor material layer and the active material layer to form a first element rod having a first inclination angle on a side surface of the first element rod;
forming a protective film and a reflective film covering the first element rod;
etching the second semiconductor material layer to form a second element rod having a second inclination angle on a side surface of the second element rod; and
forming a first contact electrode on the first element rod and forming a second contact electrode on one surface and the side surface of the second element rod.

15. The method of claim 14, the forming the first contact electrode on the first element rod and the forming the second contact electrode on the one side and the side surface of the second element rod comprises:
filling a space between the first element rod and the second element rod with a filler;
forming a first opening exposing the first element rod and a second opening exposing the one side and a portion of the side surface of the second element rod;
forming the first contact electrode in the first opening and the second contact electrode in the second opening;
flattening top surfaces of the first contact electrode and the second contact electrode; and
removing the filler.

16. The method of claim 14, wherein the forming the light emitting element further comprises forming a support on the side surface of the second element rod.

17. The method of claim 14, further comprising the forming an organic layer between the light emitting element and the pixel electrode and the common electrode

18. An electronic device comprising:
a display device for displaying an image,
wherein the display device comprising:
a substrate;
a pixel electrode and a common electrode spaced from each other on the substrate; and
a light emitting element on the pixel electrode and the common electrode,
wherein the light emitting element comprises:
a first element rod comprising a first semiconductor layer and an active layer that are sequentially stacked, and a side surface having a first inclination angle;
a second element rod comprising a second semiconductor layer, and a side surface having a second inclination angle;
a first contact electrode on the first element rod and connected to the pixel electrode; and
a second contact electrode having one side on one side of the second element rod and a portion of the side surface of the second element rod, and connected to the common electrode.

19. The electronic device of claim 18, wherein the one surface of the second contact electrode are arranged on a portion of the side surface of the second element rod.

20. The electronic device of claim 19, the light emitting element further comprises a support on a side of the second element rod and supporting the second contact electrode.
